(19) United States
(12) Patent Application Publication
(10) Pub. No.: US 2026/0076037 A1
(43) Pub. Date: Mar. 12, 2026

(54) DISPLAY PANEL AND ELECTRONIC DEVICE INCLUDING THE SAME

(71) Applicant: Samsung Display Co., Ltd., Yongin-si (KR)

(72) Inventors: Eonseok Oh, Yongin-si (KR); Kohei Ebisuno, Yongin-si (KR); Hyungsik Kim, Yongin-si (KR); Jungjoon Seo, Yongin-si (KR); Taehyun Sung, Yongin-si (KR); Jehyun Song, Yongin-si (KR); Youngbin Choi, Yongin-si (KR)

(21) Appl. No.: 19/184,827

(22) Filed: Apr. 21, 2025

(30) Foreign Application Priority Data
Sep. 9, 2024 (KR) 10-2024-0122578

(51) Int. Cl. H10K 59/122; H10K 59/80

(52) U.S. Cl. CPC H10K 59/122; H10K 59/80515; H10K 59/80516

(57) ABSTRACT

A display panel includes: an insulating layer on a substrate; a first pixel electrode on the insulating layer; a partition wall on the insulating layer, and surrounding around the first pixel electrode in a plan view; a first intermediate layer on the first pixel electrode; and an opposite electrode on the first intermediate layer, and including: a first conductive layer cut off by the partition wall; and a second conductive layer on the first conductive layer, and extending to cover a side surface and a top surface of the partition wall.

### CROSS-REFERENCE TO RELATED APPLICATION

The present application claims priority to and the benefit of Korean Patent Application No. 10-2024-0122578, filed on Sep. 9, 2024, in the Korean Intellectual Property Office, the entire disclosure of which is incorporated by reference herein.

### BACKGROUND

### 1. Field

Aspects of one or more embodiments of the present disclosure relate to a display panel, and an electronic device including the display panel.

### 2. Description of the Related Art

Recently, display panels have become thinner and lighter, and thus, the range of use of the display panels is expanding. A display panel may include display elements, and transistors, capacitors, and wires for controlling the display elements. A display element may be an organic light-emitting diode, and may include a pixel electrode, an opposite electrode, and an intermediate layer arranged between the pixel electrode and the opposite electrode.

The above information disclosed in this Background section is for enhancement of understanding of the background of the present disclosure, and therefore, it may contain information that does not constitute prior art.

### SUMMARY

Due to a leakage current through an intermediate layer, when one display element emits light, an adjacent display element may emit light together with the one display element, which may cause a brightness unevenness in an image.

One or more embodiments of the present disclosure may be directed to a display panel that displays a high-quality image, and an electronic device including the display panel. However, the present disclosure is not limited to the above aspects and features.

The above and other aspects and features will be set forth, in part, in the description that follows, and in part, may be apparent from the description, or may be learned by practicing one or more of the presented embodiments of the present disclosure.

According to one or more embodiments of the present disclosure, a display panel includes: an insulating layer on a substrate; a first pixel electrode on the insulating layer; a partition wall on the insulating layer, and surrounding around the first pixel electrode in a plan view; a first intermediate layer on the first pixel electrode; and an opposite electrode on the first intermediate layer, and including: a first conductive layer cut off by the partition wall; and a second conductive layer on the first conductive layer, and extending to cover a side surface and a top surface of the partition wall.

In an embodiment, the display panel may further include: a pixel-defining layer covering an edge of the first pixel electrode, and having a first pixel opening overlapping with the first pixel electrode. The partition wall is arranged on the pixel-defining layer, and surrounding around the first pixel opening in a plan view. The second conductive layer has a thickness of about 100 Å to about 900 Å on a surface parallel to the substrate.

In an embodiment, a cross-section of the partition wall may have a reverse tapered shape.

In an embodiment, the side surface of the partition wall may be inclined at an angle of about 130° to about 140° with respect to a top surface of the substrate.

In an embodiment, a distance from a top surface of the pixel-defining layer to the top surface of the partition wall may be about 1.1 μm to about 3 μm.

In an embodiment, in a plan view, a distance from a boundary of the first pixel opening to a boundary of the partition wall may be about 4 μm to about 7.5 μm.

In an embodiment, on the surface parallel to the substrate, the opposite electrode may have a first thickness, and on the side surface of the partition wall, the opposite electrode may have a second thickness that is about 20% to about 30% of the first thickness.

In an embodiment, the first intermediate layer may include a plurality of emitting units.

In an embodiment, the display panel may further include: a second pixel electrode and a third pixel electrode on the insulating layer, and spaced from the first pixel electrode; and a second intermediate layer on the second pixel electrode and the third pixel electrode. The partition wall may surround around the second pixel electrode and the third pixel electrode in a plan view.

In an embodiment, the display panel may further include: a pixel-defining layer covering an edge of each of the first pixel electrode, the second pixel electrode and the third pixel electrode. The pixel-defining layer has a first pixel opening overlapping with the first pixel electrode, a second pixel opening overlapping with the second pixel electrode, and a third pixel opening overlapping with the third pixel electrode.

In an embodiment, the display panel may further include: a spacer on the pixel-defining layer between the second pixel opening and the third pixel opening; and an auxiliary partition wall on the spacer.

In an embodiment, the display panel may further include: an auxiliary electrode on the insulating layer between the second pixel electrode and the third pixel electrode; and an auxiliary partition wall on the auxiliary electrode. The pixel-defining layer may have an auxiliary opening overlapping with the auxiliary electrode, and the second conductive layer may be in direct contact with the auxiliary electrode.

According to one or more embodiments of the present disclosure, a display panel includes: a first pixel electrode on a substrate; a pixel-defining layer on the substrate, and having a first pixel opening overlapping with the first pixel electrode, and a groove surrounding around the first pixel electrode; a first intermediate layer on the first pixel electrode; and an opposite electrode on the first intermediate layer, and including: a first conductive layer cut off by the groove; and a second conductive layer on the first conductive layer, and extending to cover a side surface and a bottom surface of the groove.

In an embodiment, the side surface of the groove may be inclined at an angle of about 40° to about 50° with respect to a top surface of the substrate.

In an embodiment, the first intermediate layer may include a plurality of emitting units.

In an embodiment, the display panel may further include: a second pixel electrode and a third pixel electrode on the substrate, and spaced from the first pixel electrode; and a second intermediate layer on the second pixel electrode and the third pixel electrode. The pixel-defining layer may have a second pixel opening overlapping with the second pixel electrode, and a third pixel opening overlapping with the third pixel electrode. The groove may completely surround around the second pixel opening and the third pixel opening in a plan view.

In an embodiment, the display panel may further include a spacer on the pixel-defining layer between the second pixel opening and the third pixel opening, the spacer having an auxiliary groove.

In an embodiment, The groove extends along an inner surface of the first pixel opening, and the first intermediate layer is separated into a first portion on the first pixel electrode and a second portion on the pixel-defining layer by the groove.

In an embodiment, the display panel may further include a residual sacrificial layer between the pixel-defining layer and the edge of the first pixel electrode.

According to one or more embodiments of the present disclosure, an electronic device includes: a display panel; and a lower cover forming an exterior, and including a front surface having an opening exposing a portion of the display panel. The display panel includes: a pixel electrode on a substrate; a pixel-defining layer covering an edge of the pixel electrode, and having a pixel opening overlapping with the pixel electrode; an intermediate layer on the pixel electrode; an opposite electrode on the intermediate layer; and a separator surrounding around the pixel electrode in a plan view. The intermediate layer comprises a plurality of emitting units. The opposite electrode includes: a first conductive layer cut off by the separator; and a second conductive layer on the first conductive layer, and extending to cover the separator.

In an embodiment, the intermediate layer may include a plurality of emitting units to emit light.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1A is a plan view schematically illustrating a display panel according to an embodiment;

FIG. 1B is a plan view schematically illustrating a display panel according to an embodiment;

FIG. 2 is an equivalent circuit diagram schematically illustrating a pixel included in a display panel according to an embodiment;

FIG. 3 is a cross-sectional view schematically illustrating a structure of a display element according to an embodiment;

FIG. 4 is a plan view schematically illustrating a display panel according to an embodiment;

FIG. 5 is a cross-sectional view schematically illustrating a display panel according to an embodiment;

FIG. 6 is a cross-sectional view schematically illustrating a partition wall according to an embodiment;

FIG. 7 is a cross-sectional view schematically illustrating a display panel according to an embodiment;

FIG. 8 is a cross-sectional view schematically illustrating a groove according to an embodiment;

FIG. 9 is a plan view schematically illustrating a display panel according to an embodiment;

FIG. 10 is a cross-sectional view schematically illustrating a display panel according to an embodiment;

FIG. 11 is a plan view schematically illustrating a display panel according to an embodiment;

FIG. 12A is a cross-sectional view schematically illustrating a display panel according to an embodiment;

FIG. 12B is a cross-sectional view schematically illustrating a display panel according to an embodiment;

FIG. 13 is a cross-sectional view schematically illustrating a display panel according to an embodiment;

FIG. 14 is a plan view schematically illustrating a display panel according to an embodiment;

FIG. 15 is a cross-sectional view schematically illustrating a display panel according to an embodiment;

FIG. 16 is a cross-sectional view schematically illustrating an organic light-emitting diode according to an embodiment;

FIG. 17 is a cross-sectional view schematically illustrating a display panel according to an embodiment;

FIG. 18 is a perspective view schematically illustrating an electronic device according to an embodiment; and

FIG. 19 is a block diagram schematically illustrating an electronic device according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

As used herein, the phrase “in a plan view” may refer to a view of an object part from above (e.g., when viewed in a direction perpendicular to a top surface of a substrate), and the phrases “in a cross-section” and “in a cross-sectional view” may refer to a vertical cross-section of an object part that is viewed from the side.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

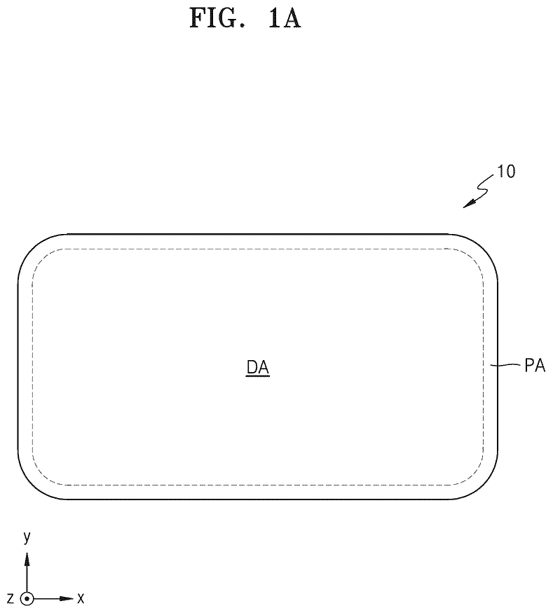

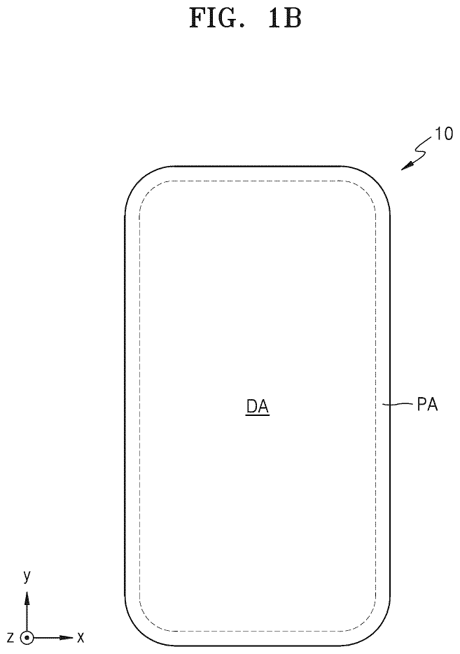

FIG. 1A is a plan view schematically illustrating a display panel according to an embodiment. FIG. 1B is a plan view schematically illustrating a display panel according to an embodiment.

Referring to FIGS. 1A and 1B, a display panel 10 may include a display region DA to display an image, and a peripheral region PA outside the display region DA. The display panel 10 may provide an image (e.g., a certain or predetermined image) by using light emitted from a plurality of pixels arranged in the display region DA. As used herein, a pixel represents a sub-pixel that emits light of a desired color (e.g., a certain or predetermined color). For example, each of the pixels may emit red light, green light, or blue light. As another example, each of the pixels may emit red light, green light, blue light, or white light.

In a plan view, the display region DA may have a quadrangular shape. In another embodiment, the display region DA may have another suitable polygonal shape, a circular shape, an elliptical shape, or an irregular shape. Corners of the edge of the display region DA may have a rounded shape.

In an embodiment, as shown in FIG. 1A, the display region DA of the display panel 10 may have a length in a first direction (e.g., the x direction) that is greater than a length in a second direction (e.g., the y direction). In another embodiment, as shown in FIG. 1B, the display region DA of the display panel 10 may have a length in the first direction (e.g., the x direction) that is smaller than a length in the second direction (e.g., the y direction).

The peripheral region PA is arranged around the display region DA, and the peripheral region PA may surround (e.g., around a periphery of) at least a portion of the display region DA. In an embodiment, the peripheral region PA may be a kind of non-display region in which the pixels are not arranged. Wires to transmit electrical signals to be applied to the display region DA, circuits, and pads to which a printed circuit board or a driver IC chip is attached, may be arranged in the peripheral region PA.

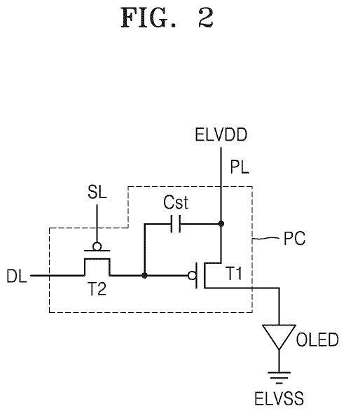

FIG. 2 is an equivalent circuit diagram schematically illustrating a pixel included in a display panel according to an embodiment.

Referring to FIG. 2, a pixel included in the display panel 10 may include a pixel circuit PC, and an organic light-emitting diode OLED electrically connected to the pixel circuit PC.

The pixel circuit PC may include a first transistor T1, a second transistor T2, and a capacitor Cst. The pixel circuit PC may be electrically connected to a scan line SL and a data line DL. The first transistor T1 may be a driving transistor, and the second transistor T2 may be a switching transistor. The second transistor T2 may be electrically connected to the scan line SL and the data line DL, and may transmit, to the first transistor T1, a data signal input through the data line DL according to a scan signal input through the scan line SL.

The capacitor Cst may be connected to the second transistor T2 and a driving voltage line PL, and may store a voltage corresponding to a difference between the data signal received from the second transistor T2 and a driving voltage ELVDD supplied to the driving voltage line PL.

The organic light-emitting diode OLED may include a pixel electrode (e.g., an anode), an opposite electrode (e.g., a cathode), and an intermediate layer arranged between the pixel electrode and the opposite electrode. A common voltage ELVSS may be applied to the opposite electrode.

The first transistor T1 may be connected to the driving voltage line PL and the capacitor Cst, and may control a driving current flowing from the driving voltage line PL to the organic light-emitting diode OLED according to a value stored in the capacitor Cst. The organic light-emitting diode OLED may emit light having a desired luminance (e.g., a certain or predetermined luminance) according to the driving current.

FIG. 2 illustrates that the pixel circuit PC includes two transistors and one capacitor, but the present disclosure is not limited thereto. In another embodiment, the pixel circuit PC may include at least three transistors and/or at least two capacitors.

In addition, FIG. 2 illustrates that the first transistor T1 and the second transistor T2 are each provided as a P-type transistor, but the present disclosure is not limited thereto. In another embodiment, some of the transistors included in the pixel circuit PC may each be provided as an N-type transistor, and others may each be provided as a P-type transistor. In another embodiment, the transistors may each be provided as an N-type transistor.

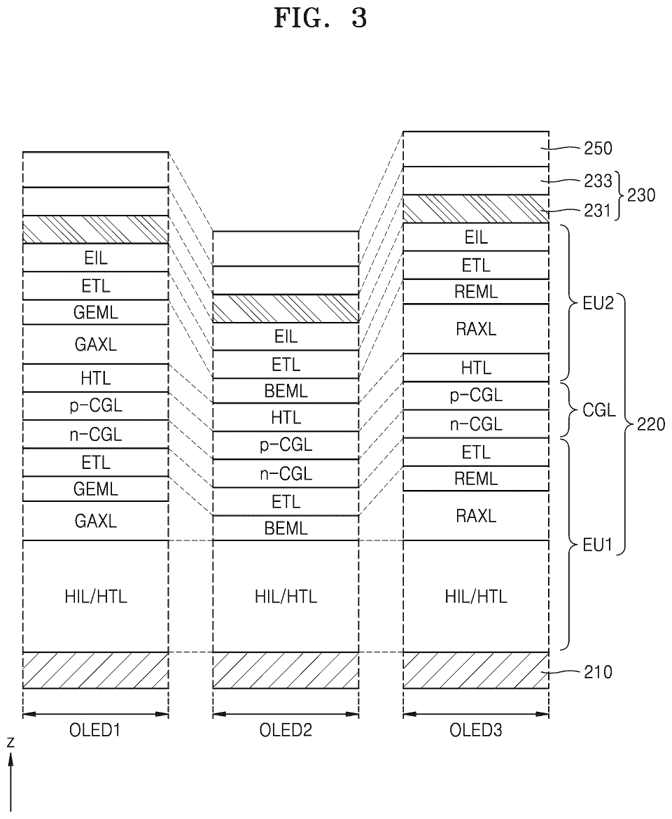

FIG. 3 is a cross-sectional view schematically illustrating a structure of a display element according to an embodiment.

Referring to FIG. 3, a display element according to an embodiment may be an organic light-emitting diode. Each of a first organic light-emitting diode OLED1 included in a first pixel, a second organic light-emitting diode OLED2 included in a second pixel, and a third organic light-emitting diode OLED3 included in a third pixel may include a pixel electrode 210 (e.g., an anode), an opposite electrode 230 (e.g., a cathode), and an intermediate layer 220 arranged between the pixel electrode 210 and the opposite electrode 230. The pixel electrodes 210 may be independently provided in the first organic light-emitting diode OLED1, the second organic light-emitting diode OLED2, and the third organic light-emitting diode OLED3, respectively.

The pixel electrode 210 may include a transparent conductive oxide, such as indium tin oxide (ITO), indium zinc oxide (IZO), zinc oxide (ZnO), indium oxide (In₂O₃), indium gallium oxide (IGO), indium gallium zinc oxide (IGZO), gallium zinc oxide (GZO), or aluminum zinc oxide (AZO). The pixel electrode 210 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or suitable compounds thereof. For example, the pixel electrode 210 may have a three-layered structure of ITO/Ag/ITO.

The opposite electrode 230 may be arranged on the intermediate layer 220. The opposite electrode 230 may include a metal with a low work function, an alloy, an electrically conductive compound, or a suitable combination thereof. The opposite electrode 230 may include a first conductive layer 231 and a second conductive layer 233.

The first conductive layer 231 may include silver (Ag) or a silver alloy. The silver alloy may be a silver magnesium alloy (AgMg), a silver ytterbium alloy (AgYb), a silver palladium copper alloy (AgPdCu), or a silver lithium alloy (AgLi), each having a silver content of 90% or more. The first conductive layer 231 may be formed through a thermal evaporation process.

The second conductive layer 233 may include a transparent conductive oxide. The transparent conductive oxide may include indium tin oxide (ITO), indium zinc oxide (IZO), zinc oxide (ZnO), indium oxide (In₂O₃), indium gallium oxide (IGO), indium gallium zinc oxide (IGZO), gallium zinc oxide (GZO), or aluminum zinc oxide (AZO). The second conductive layer 233 may be formed through a sputtering process. The second conductive layer 233 may be continuously and commonly provided in the first organic light-emitting diode OLED1, the second organic light-emitting diode OLED2, and the third organic light-emitting diode OLED3.

The intermediate layer 220 may include a polymer or a low-molecular weight organic material that emits light of a desired color (e.g., a certain or predetermined color). The intermediate layer 220 may further include a metal-containing compound such as an organometallic compound, an inorganic material such as a quantum dot or the like, in addition to various suitable organic materials. In an embodiment, the intermediate layer 220 may include at least two emitting units (e.g., at least two emitting layers or stacks) sequentially stacked between the pixel electrode 210 and the opposite electrode 230, and a charge generation layer CGL arranged between the two emitting units. When the intermediate layer 220 includes a plurality of emitting units (e.g., a plurality of emitting layers or stacks) and the charge generation layer CGL, the organic light-emitting diode may be referred to as a tandem light-emitting device.

One emitting unit (e.g., one emitting layer or stack) may include an emission layer, a first functional layer, and a second functional layer. The first functional layer and the second functional layer may be arranged under and above the emission layer, respectively. The first functional layer may include a hole transport layer HTL, or may include a hole injection layer and hole transport layer HIL/HTL. The second functional layer may be an optional component that is arranged above the emission layer. The second functional layer may include an electron transport layer ETL and/or an electron injection layer EIL.

The charge generation layer CGL may include a negative charge generation layer n-CGL and a positive charge generation layer p-CGL. The negative charge generation layer n-CGL may be an n-type charge generation layer. The negative charge generation layer n-CGL may supply electrons. The negative charge generation layer n-CGL may include a host and a dopant. The host may include an organic material. The dopant may include a metal material. The positive charge generation layer p-CGL may be a p-type charge generation layer. The positive charge generation layer p-CGL may supply holes. The positive charge generation layer p-CGL may include a host and a dopant. The host may include an organic material. The dopant may include a metal material.

The intermediate layer 220 of each of the first organic light-emitting diode OLED1, the second organic light-emitting diode OLED2, and the third organic light-emitting diode OLED3 may include first and second emitting units (e.g., first and second emitting layers or stacks) EU1 and EU2 that are sequentially stacked, and the charge generation layer CGL between the first emitting unit EU1 and the second emitting unit EU2.

The first emitting unit EU1 of the first organic light-emitting diode OLED1 may include the hole injection layer and hole transport layer HIL/HTL, a green auxiliary layer GAXL, a green emission layer GEML, and the electron transport layer ETL, which are sequentially stacked on the pixel electrode 210. The first emitting unit EU1 of the second organic light-emitting diode OLED2 may include the hole injection layer and hole transport layer HIL/HTL, a blue emission layer BEML, and the electron transport layer ETL, which are sequentially stacked on the pixel electrode 210. The first emitting unit EU1 of the third organic light-emitting diode OLED3 may include the hole injection layer and hole transport layer HIL/HTL, a red auxiliary layer RAXL, a red emission layer REML, and the electron transport layer ETL, which are sequentially stacked on the pixel electrode 210. The red auxiliary layer RAXL and the green auxiliary layer GAXL are layers that may be included or added to adjust a resonance distance, and may include a resonance auxiliary material. In an embodiment, the red auxiliary layer RAXL and the green auxiliary layer GAXL may include the same material as that of the hole transport layer HTL. The green auxiliary layer GAXL may be omitted as needed or desired.

The second emitting unit EU2 of the first organic light-emitting diode OLED1 may include the hole transport layer HTL, the green auxiliary layer GAXL, the green emission layer GEML, the electron transport layer ETL, and the electron injection layer EIL, which are sequentially stacked on the charge generation layer CGL. The second emitting unit EU2 of the second organic light-emitting diode OLED2 may include the hole transport layer HTL, the blue emission layer BEML, the electron transport layer ETL, and the electron injection layer EIL, which are sequentially stacked on the charge generation layer CGL. The second emitting unit EU2 of the third organic light-emitting diode OLED3 may include the hole transport layer HTL, the red auxiliary layer RAXL, the red emission layer REML, the electron transport layer ETL, and the electron injection layer EIL, which are sequentially stacked on the charge generation layer CGL.

The green emission layer GEML and the green auxiliary layer GAXL may be patterned to correspond to the first organic light-emitting diode OLED1. The blue emission layer BEML may be patterned to correspond to the second organic light-emitting diode OLED2. The red emission layer REML and the red auxiliary layer RAXL may be patterned to correspond to the third organic light-emitting diode OLED3.

The thickness of each of the green emission layer GEML, the blue emission layer BEML, and the red emission layer REML may be determined according to a resonance distance. In some embodiments, the hole transport layer HTL, the hole injection layer and hole transport layer HIL/HTL, the electron transport layer ETL, the electron injection layer EIL, and the charge generation layer CGL may be deposited on the entire or substantially the entire surface of the display region DA. At least one of the hole transport layer HTL, the hole injection layer and hole transport layer HIL/HTL, the electron transport layer ETL, the electron injection layer EIL, or the charge generation layer CGL may be separated by a separator, and may be independently provided in each of the first organic light-emitting diode OLED1, the second organic light-emitting diode OLED2, and the third organic light-emitting diode OLED3. In some embodiments, the first conductive layer 231 may be divided by the separator, and may be independently provided in each of the first organic light-emitting diode OLED1, the second organic light-emitting diode OLED2, and the third organic light-emitting diode OLED3. In some embodiments, the first conductive layer 231 may be continuously and commonly provided in the first organic light-emitting diode OLED1, the second organic light-emitting diode OLED2, and the third organic light-emitting diode OLED3.

A capping layer 250 may be arranged on the opposite electrode 230. The capping layer 250 may serve to improve a luminescence efficiency based on the principle of constructive interference. The capping layer 250 may include a suitable material having a refractive index of 1.6 (e.g., at 589 nm). The capping layer 250 may be an organic capping layer including an organic material, an inorganic capping layer including an inorganic material, or a composite capping layer including an organic material and an inorganic material. In an embodiment, the capping layer 250 may include lithium fluoride (LiF).

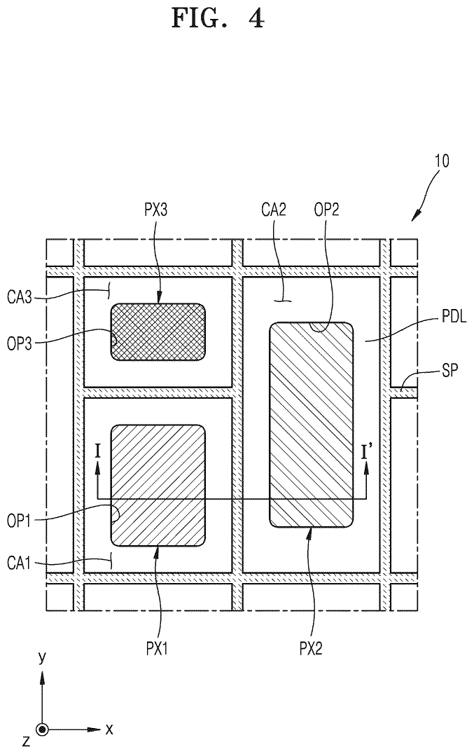

FIG. 4 is a plan view schematically illustrating a display panel according to an embodiment.

FIG. 4 illustrates first to third pixels PX1, PX2, and PX3, a pixel-defining layer PDL, and a separator SP, which are arranged in the display region DA of the display panel 10. The pixels PX1, PX2, and PX3 shown in FIG. 4 represent emission regions of the pixels PX1, PX2, and PX3 defined by first to third pixel openings OP1, OP2, and OP3 in the pixel-defining layer PDL.

Referring to FIG. 4, the pixels PX1, PX2, and PX3 may be arranged in the display region DA of the display panel 10. The pixels PX1, PX2, and PX3 may include the first pixel PX1 that emits green light, the second pixel PX2 that emits blue light, and the third pixel PX3 that emits red light. The green light may be light in a wavelength band of about 495 nm to about 580 nm, the red light may be light in a wavelength band of about 580 nm to about 780 nm, and the blue light may be light in a wavelength band of about 400 nm to about 495 nm. In an embodiment, each of the first pixel PX1, the second pixel PX2, and the third pixel PX3 may emit white light.

The first pixel PX1, the second pixel PX2, and the third pixel PX3 may be arranged according to a suitable rule (e.g., a certain or predetermined rule), such as a stripe arrangement or a diamond shape arrangement (e.g., a PENTILE® arrangement, PENTILE® being a duly registered trademark of Samsung Display Co., Ltd.). In an embodiment, the third pixel PX3 and the first pixel PX1 are alternately arranged along the second direction (e.g., the y direction) to form a first pixel column, and the second pixel PX2 is repeatedly arranged along the second direction (e.g., the y direction) to form a second pixel column. The first pixel column and the second pixel column may be alternately arranged along the first direction (e.g., the x direction).

The pixel-defining layer PDL may define the pixel openings OP1, OP2, and OP3. The pixel-defining layer PDL may define an emission region of each of the pixels PX1, PX2, and PX3 through the pixel openings OP1, OP2, and OP3. For example, the emission region of the first pixel PX1 may be defined by the first pixel opening OP1, the emission region of the second pixel PX2 may be defined by the second pixel opening OP2, and the emission region of the third pixel PX3 may be defined by the third pixel opening OP3.

Each of the first pixel opening OP1, the second pixel opening OP2, and the third pixel opening OP3 may have a substantially quadrangular shape in a plan view, but the present disclosure is not limited thereto. In another embodiment, each of the first pixel opening OP1, the second pixel opening OP2, and the third pixel opening OP3 may have another suitable polygonal shape, a circular shape, or an elliptical shape. The first pixel opening OP1, the second pixel opening OP2, and the third pixel opening OP3 may have a chamfered shape.

As shown in FIG. 4, the first pixel opening OP1, the second pixel opening OP2, and the third pixel opening OP3 may have different sizes (e.g., different areas) from each other. For example, the size (e.g., the area) of the second pixel opening OP2 may be greater than the size (e.g., the area) of the first pixel opening OP1 and the size (e.g., the area) of the third pixel opening OP3. The size (e.g., the area) of the first pixel opening OP1 may be greater than or equal to the size (e.g., the area) of the third pixel opening OP3. In another embodiment, the first pixel opening OP1, the second pixel opening OP2, and the third pixel opening OP3 may have the same or substantially the same size (e.g., area) as each other.

The pixel-defining layer PDL may include an organic insulating material, such as benzocyclobutene (BCB), polyimide, or hexamethyldisiloxane (HMDSO). The pixel-defining layer PDL may be black. In an embodiment, the pixel-defining layer PDL may include a light-blocking material and may be black. The light-blocking material may include a resin or a paste including carbon black, carbon nanotubes, or a black dye, metal particles, such as nickel (Ni), aluminum (Al), molybdenum (Mo), and/or suitable alloys thereof, metal oxide particles (e.g., chromium oxide), or metal nitride particles (e.g., chromium nitride). When the pixel-defining layer PDL includes a light-blocking material, a reflection caused by metal structures arranged under the pixel-defining layer PDL may be reduced.

The display panel 10 may include the separator SP. In an embodiment, the separator SP may be a partition wall arranged on the pixel-defining layer PDL. In another embodiment, the separator SP may be a groove defined by the pixel-defining layer PDL. The separator SP may be arranged to at least partially surround (e.g., around a periphery of) each of the first pixel opening OP1, the second pixel opening OP2, and the third pixel opening OP3 in a plan view. In an embodiment, the separator SP may be arranged to completely surround (e.g., around a periphery of) each of the first pixel opening OP1, the second pixel opening OP2, and the third pixel opening OP3 in a plan view. For example, the separator SP may define a plurality of cells having a closed shape in a plan view. The separator SP may have a mesh structure. In another embodiment, the separator SP may surround (e.g., around a periphery of) each of the first pixel opening OP1, the second pixel opening OP2, and the third pixel opening OP3 in a plan view, and may have at least one side that is open. The plurality of cells defined by the separator SP may have at least one side that is open, and thus, may be connected to each other.

One of the first pixel PX1, the second pixel PX2, or the third pixel PX3 may be arranged in each of the plurality of cells. For example, the first pixel PX1 may be arranged in a first region CA1 defined by a first cell, the second pixel PX2 may be arranged in a second region CA2 defined by a second cell, and the third pixel PX3 may be arranged in a third region CA3 defined by a third cell. The separator SP may divide the intermediate layer 220 arranged in each of the first region CA1, the second region CA2, and the third region CA3, to reduce, between adjacent pixels, a leakage current through the intermediate layer 220.

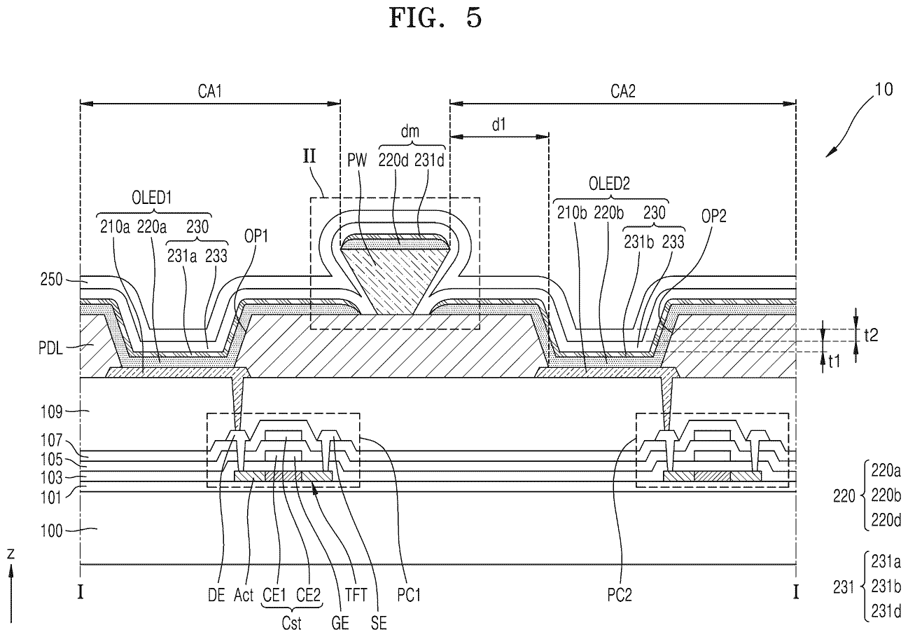

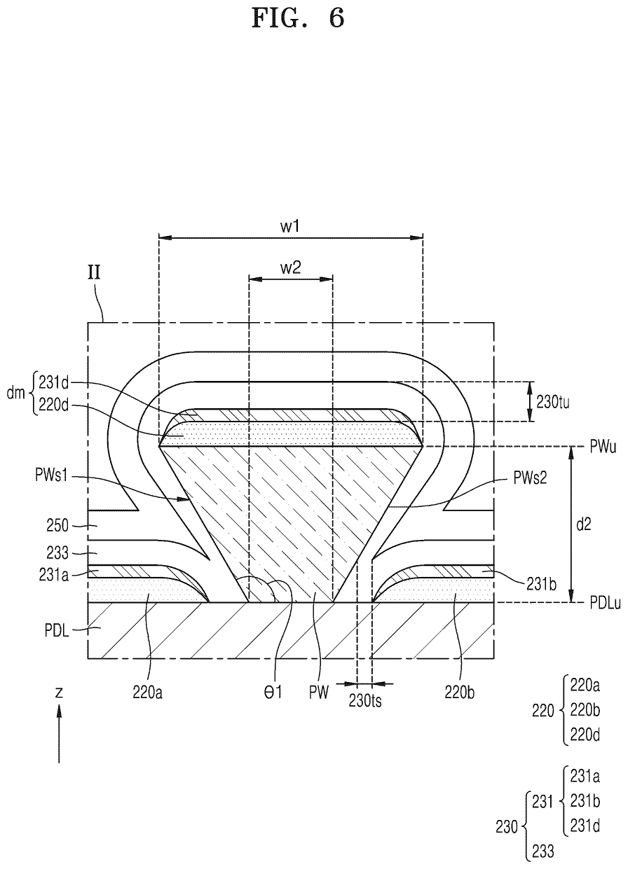

FIG. 5 is a cross-sectional view schematically illustrating a display panel according to an embodiment. FIG. 6 is a cross-sectional view schematically illustrating a partition wall according to an embodiment.

FIG. 5 schematically illustrates a cross-section of the display panel 10 taken along the line I-I′ of FIG. 4, and FIG. 6 illustrates an enlarged view of the region II of FIG. 5. FIGS. 5 and 6 illustrate that the separator SP includes (e.g., is) a partition wall PW arranged on the pixel-defining layer PDL.

Referring to FIG. 5, the display panel 10 may include a substrate 100. The substrate 100 may include glass, a metal, or a polymer resin. The polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or suitable mixtures thereof. In an embodiment, the substrate 100 may have a multilayered structure including at least two base layers, each including the polymer resin, and an inorganic material layer arranged between the at least two base layers.

In another embodiment, the substrate 100 may include a semiconductor material, for example, such as a Group IV semiconductor, a Group III-V compound semiconductor, or a Group II-VI compound semiconductor. In other words, the substrate 100 may be a semiconductor substrate including a semiconductor material. In more detail, the substrate 100 may be a silicon substrate (e.g., a silicon semiconductor substrate) including silicon (Si). In a process of manufacturing the display panel 10 by using the substrate 100 including a semiconductor material, a process of manufacturing a thin-film transistor that is commonly used in the semiconductor technology field may be applied to form an ultra-small pixel. Therefore, the display panel 10 may display an ultra-high resolution image.

A buffer layer 101 may be arranged on the substrate 100. The buffer layer 101 may include an inorganic material, such as silicon oxide, silicon nitride, and/or silicon oxynitride. The buffer layer 101 may increase the smoothness of a top surface of the substrate 100, or may prevent or minimize a penetration of impurities from the substrate 100 into an active layer Act of a thin-film transistor TFT.

A first pixel circuit PC1 and a second pixel circuit PC2 may be arranged on the buffer layer 101. The first pixel circuit PC1 and the second pixel circuit PC2 may have the same or similar structures as each other. Hereinafter, for convenience of illustration, the first pixel circuit PC1 may be mainly described in more detail.

The first pixel circuit PC1 may include the thin-film transistor TFT and the capacitor Cst. The thin-film transistor TFT shown in FIG. 5 may correspond to the first transistor T1 described above with reference to FIG. 2. The thin-film transistor TFT may include the active layer Act, a gate electrode GE, a source electrode SE, and a drain electrode DE.

The active layer Act may be arranged on the buffer layer 101. In an embodiment, the active layer Act may include a silicon-based semiconductor material, for example, such as amorphous silicon or polycrystalline silicon. In another embodiment, the active layer Act may include an oxide-based semiconductor material, for example, such as oxides of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn).

In another embodiment, when the substrate 100 is provided as a semiconductor substrate, the buffer layer 101 may be omitted, and the active layer Act may be formed as a portion of the substrate 100.

A gate insulating layer 103 may be arranged on the active layer Act, and the gate electrode GE may be arranged on the gate insulating layer 103 to overlap with the active layer Act in a plan view. The gate electrode GE may include a conductive material, such as molybdenum (Mo), aluminum (AI), copper (Cu), titanium (Ti), indium tin oxide (ITO), or indium zinc oxide (IZO), and may be formed as multilayers or a single layer, each including at least one of the above materials.

A first interlayer insulating layer 105 may be arranged on the gate electrode GE, and a second capacitor electrode CE2 may be arranged on the first interlayer insulating layer 105. At least a portion of the gate electrode GE may overlap with the second capacitor electrode CE2 in a plan view, and may function as a first capacitor electrode CE1 of the capacitor Cst. In other words, the gate electrode GE and the first capacitor electrode CE1 may be integrally provided with each other as a single body. The second capacitor electrode CE2 may include a conductive material, such as molybdenum (Mo), aluminum (AI), copper (Cu), titanium (Ti), indium tin oxide (ITO), or indium zinc oxide (IZO), and may be formed as multilayers or a single layer, each including at least one of the above materials.

A second interlayer insulating layer 107 may be arranged on the second capacitor electrode CE2, and the source electrode SE and the drain electrode DE may be arranged on the second interlayer insulating layer 107. The source electrode SE and the drain electrode DE may each include a conductive material, such as molybdenum (Mo), aluminum (AI), copper (Cu), titanium (Ti), indium tin oxide (ITO), or indium zinc oxide (IZO), and may each be formed as multilayers or a single layer, each including at least one of the above materials. For example, the source electrode SE and the drain electrode DE may each have a multilayered structure of Ti/Al/Ti.

The gate insulating layer 103, the first interlayer insulating layer 105, and the second interlayer insulating layer 107 may each include an inorganic material, such as silicon oxide, silicon nitride, and/or silicon oxynitride, and may each be formed as multilayers or a single layer, each including at least one of the above materials.

A planarization layer 109 may be arranged on the first pixel circuit PC1 and the second pixel circuit PC2. The planarization layer 109 may include an organic insulating material. For example, the planarization layer 109 may include benzocyclobutene (BCB), polyimide, hexamethyldisiloxane (HMDSO), polymethylmethacrylate (PMMA), polystyrene, polymer derivatives with phenolic groups, acryl-based polymers, imide polymers, aryl ether-based polymers, amide-based polymers, fluorine-based polymers, p-xylene-based polymers, vinyl alcohol-based polymers, or suitable mixtures thereof.

The first organic light-emitting diode OLED1 and the second organic light-emitting diode OLED2 may be spaced apart from each other on the planarization layer 109. In an embodiment, the first organic light-emitting diode OLED1 and the second organic light-emitting diode OLED2 may emit light of different colors from each other. For example, the first organic light-emitting diode OLED1 may emit green light, and the second organic light-emitting diode OLED2 may emit blue light. In another embodiment, the first organic light-emitting diode OLED1 and the second organic light-emitting diode OLED2 may emit light of the same color as each other. For example, the first organic light-emitting diode OLED1 and the second organic light-emitting diode OLED2 may each emit white light. Hereinafter, for convenience of illustration, a case in which the first organic light-emitting diode OLED1 and the second organic light-emitting diode OLED2 emit light of different colors from each other may be mainly described in more detail.

The first organic light-emitting diode OLED1 may include a first pixel electrode 210a, a first intermediate layer 220a, and the opposite electrode 230. The opposite electrode 230 of the first organic light-emitting diode OLED1 may include a first-first conductive layer 231a and the second conductive layer 233. The second organic light-emitting diode OLED2 may include a second pixel electrode 210b, a second intermediate layer 220b, and the opposite electrode 230. The opposite electrode 230 of the second organic light-emitting diode OLED2 may include a first-second conductive layer 231b and the second conductive layer 233.

The first pixel electrode 210a may be electrically connected to the first pixel circuit PC1 through a contact hole penetrating the planarization layer 109. In other words, the first organic light-emitting diode OLED1 may be electrically connected to the first pixel circuit PC1. Likewise, the second pixel electrode 210b may be electrically connected to the second pixel circuit PC2 through a contact hole penetrating the planarization layer 109. The second organic light-emitting diode OLED2 may be electrically connected to the second pixel circuit PC2. Each of the first pixel electrode 210a and the second pixel electrode 210b may correspond to the pixel electrode 210 described above with reference to FIG. 3.

The pixel-defining layer PDL may be arranged to cover an edge of each of the first pixel electrode 210a and the second pixel electrode 210b. The pixel-defining layer PDL may define the first pixel opening OP1 exposing a portion of the first pixel electrode 210a, and the second pixel opening OP2 exposing a portion of the second pixel electrode 210b. The pixel-defining layer PDL may prevent or substantially prevent arcs from occurring, by increasing a distance between the edge of the first pixel electrode 210a and the opposite electrode 230 and a distance between the edge of the second pixel electrode 210b and the opposite electrode 230.

The partition wall PW may be arranged on the pixel-defining layer PDL, as the separator SP. The partition wall PW may be in direct contact with a top surface of the pixel-defining layer PDL. In an embodiment, the partition wall PW may include an organic insulating material. In an embodiment, the partition wall PW may include a negative photoresist material of which a solubility with respect to a developer is reduced by exposure. In another embodiment, the partition wall PW may have a multilayered structure of an organic insulating material layer and an inorganic insulating material layer. In another embodiment, the partition wall PW may include an inorganic insulating material.

A cross-section of the partition wall PW may have a reverse tapered shape having a smaller width at a lower end than that of an upper end. For example, as shown in FIG. 6, a first width w1, which is the width of a top surface PWu of the partition wall PW, may be greater than a second width w2, which is the width of a bottom surface of the partition wall PW. In an embodiment, in order to form the partition wall PW in the reverse tapered shape, the first width w1 may be about 5 μm or more.

The partition wall PW may have a first side surface PWs1 and a second side surface PWs2, which are opposite to each other. The first side surface PWs1 of the partition wall PW may be inclined by a first angle θ1 with respect to a top surface PDLu of the pixel-defining layer PDL.

In an embodiment, the first angle θ1 may be about 130° to about 140°. When the first angle θ1 is less than 130°, the intermediate layer 220 may not be completely cut off by the partition wall PW and may remain connected, and thus, a leakage current may flow between adjacent organic light-emitting diodes. When the first angle θ1 is greater than 140°, the opposite electrode 230 may become excessively thin at the first side surface PWs1 and the second side surface PWs2 of the partition wall PW or may be cut off, and thus, the organic light-emitting diodes may not emit light.

The partition wall PW may be arranged between the pixel openings OP1, OP2, and OP3, and an edge of the top surface PWu of the partition wall PW may be spaced apart by a first distance d1 from a boundary of an adjacent pixel opening (e.g., in a plan view). The first distance d1 may be about 4 μm to about 7.5 μm. When the first distance d1 is less than 4 μm, the pixel openings OP1, OP2, and OP3 may be damaged in a process of forming the partition wall PW. When the first distance d1 is greater than 7.5 μm, a resolution of the display panel 10 may be reduced, and the opposite electrode 230 may be broken.

The top surface PWu of the partition wall PW may be spaced apart by a second distance d2 from the top surface PDLu of the pixel-defining layer PDL. The second distance d2 may be about 1.1 μm to about 3 μm. When the second distance d2 is less than 1.1 μm, the intermediate layer 220 may not be completely cut off by the partition wall PW and may remain connected. When the second distance d2 is greater than 3 μm, the opposite electrode 230 may become excessively thin at the first side surface PWs1 and the second side surface PWs2 of the partition wall PW or may be cut off.

The intermediate layer 220 may be arranged on the pixel-defining layer PDL. The intermediate layer 220 may include the first intermediate layer 220a arranged in the first region CA1, the second intermediate layer 220b arranged in the second region CA2, and a dummy intermediate layer 220d arranged on the top surface PWu of the partition wall PW.

The intermediate layer 220 may include a plurality of emitting units (e.g., a plurality of emitting layers or stacks), and the charge generation layer CGL arranged between the emitting units, as described with reference to FIG. 3. In other words, each of the first organic light-emitting diode OLED1 and the second organic light-emitting diode OLED2 may be referred to as a tandem light-emitting device.

The green emission layer GEML and the green auxiliary layer GAXL, which form the intermediate layer 220, may be arranged to correspond to the first pixel opening OP1. The blue emission layer BEML may be arranged to correspond to the second pixel opening OP2. The red emission layer REML and the red auxiliary layer RAXL may be arranged to correspond to the third pixel opening OP3. Each of the hole injection layer and hole transport layer HIL/HTL, the electron transport layer ETL, the charge generation layer CGL, the hole transport layer HTL, and the electron injection layer EIL, which form the intermediate layer 220, may be formed on the entire or substantially the entire surface of the display region DA through a thermal evaporation process. The intermediate layer 220 may be divided into the first intermediate layer 220a, the second intermediate layer 220b, and the dummy intermediate layer 220d, by the partition wall PW having the reverse tapered shape. A material for forming the intermediate layer 220 may have a low step coverage, and thus, may not be deposited on the first side surface PWs1 and the second side surface PWs2 of the partition wall PW, or may be divided without being connected even when deposited on a portion of each of the first side surface PWs1 and the second side surface PWs2 of the partition wall PW. In other words, the first intermediate layer 220a may be cut off by the first side surface PWs1 of the partition wall PW, and the second intermediate layer 220b may be cut off by the second side surface PWs2 of the partition wall PW. The dummy intermediate layer 220d may be arranged on the top surface PWu of the partition wall PW, and may be spaced apart from the first intermediate layer 220a and the second intermediate layer 220b in a third direction (e.g., the z direction). The first intermediate layer 220a and the second intermediate layer 220b may be spaced apart from each other with the dummy intermediate layer 220d therebetween, thereby reducing or preventing a leakage current from flowing between the adjacent first organic light-emitting diode OLED1 and second organic light-emitting diode OLED2 through the intermediate layer 220. Therefore, the display panel 10 may display a high-quality image without having a brightness unevenness or a color mixing.

The opposite electrode 230 may be arranged on the intermediate layer 220. The opposite electrode 230 may include the first conductive layer 231 and the second conductive layer 233. The first conductive layer 231 may include the first-first conductive layer 231a arranged in the first region CA1, the first-second conductive layer 231b arranged in the second region CA2, and a dummy conductive layer 231d arranged on the top surface PWu of the partition wall PW.

The first conductive layer 231 may include silver (Ag) or a silver alloy, and may be formed on the entire or substantially the entire surface of the display region DA through a thermal evaporation process. The first conductive layer 231 may be divided into the first-first conductive layer 231a, the first-second conductive layer 231b, and the dummy conductive layer 231d, by the partition wall PW having the reverse tapered shape. A material for forming the first conductive layer 231 may have a low step coverage, and thus, may not be deposited on a side surface of the partition wall PW, or may be divided without being connected even when deposited on a portion of the side surface. In other words, the first-first conductive layer 231a may be cut off by the first side surface PWs1 of the partition wall PW, and the first-second conductive layer 231b may be cut off by the second side surface PWs2 of the partition wall PW. The dummy conductive layer 231d may be arranged on the top surface PWu of the partition wall PW, and may be spaced apart from the first-first conductive layer 231a and the first-second conductive layer 231b in the third direction (e.g., the z direction).

The second conductive layer 233 may include a transparent conductive oxide, and may be formed on the entire or substantially the entire surface of the display region DA through a sputtering process. The second conductive layer 233 has a relatively high step coverage, and thus, may extend to cover the first side surface PWs1, the top surface PWu, and the second side surface PWs2 of the partition wall PW. In other words, the second conductive layer 233 may be commonly provided in the first organic light-emitting diode OLED1 and the second organic light-emitting diode OLED2.

Referring to FIG. 6, the opposite electrode 230 may have a first thickness 230tu on a surface parallel to or substantially parallel to the substrate 100, for example, such as on the top surface PWu of the partition wall PW. The opposite electrode 230 may have a second thickness 230ts at a portion where the opposite electrode 230 at each of the first side surface PWs1 and the second side surface PWs2 of the partition wall PW is the thinnest. The second thickness 230ts may be about 20% to about 30% of the first thickness 230tu. In an embodiment, in order to prevent the resistance of the opposite electrode 230 from excessively increasing or prevent the opposite electrode 230 from being broken, the second thickness 230ts may be about 100 Å.

In an embodiment, a thickness t1 of the second conductive layer 233 may be about 100 Å to about 900 Å on the first pixel electrode 210a and the second pixel electrode 210b. When the thickness t1 of the second conductive layer 233 is less than 100 Å, the opposite electrode 230 may be cut off by the partition wall PW, and thus, the first organic light-emitting diode OLED1 and the second organic light-emitting diode OLED2 may not emit light. When the thickness t1 of the second conductive layer 233 is greater than 900 Å, a time used for a process of depositing a transparent conductive oxide may be increased, resulting in a decrease in mass productivity of the display panel 10.

In some embodiments, in order to prevent the resistance from increasing due to a portion of the second conductive layer 233 becoming excessively thin at the first side surface PWs1 and the second side surface PWs2 of the partition wall PW, the thickness t1 of the second conductive layer 233 may be greater than or equal to about 500 Å.

The capping layer 250 may be arranged on the opposite electrode 230. In an embodiment, on the first pixel electrode 210a and the second pixel electrode 210b, the sum of the thickness t1 of the second conductive layer 233 of the opposite electrode 230 and a thickness t2 of the capping layer 250 may be about 1,200 Å. The luminescence efficiency of the organic light-emitting diodes may be improved based on the principle of constructive interference by adjusting the thickness t2 of the capping layer 250, such that the sum of the thickness t1 of the second conductive layer 233 of the opposite electrode 230 and the thickness t2 of the capping layer 250 is about 1,200 Å.

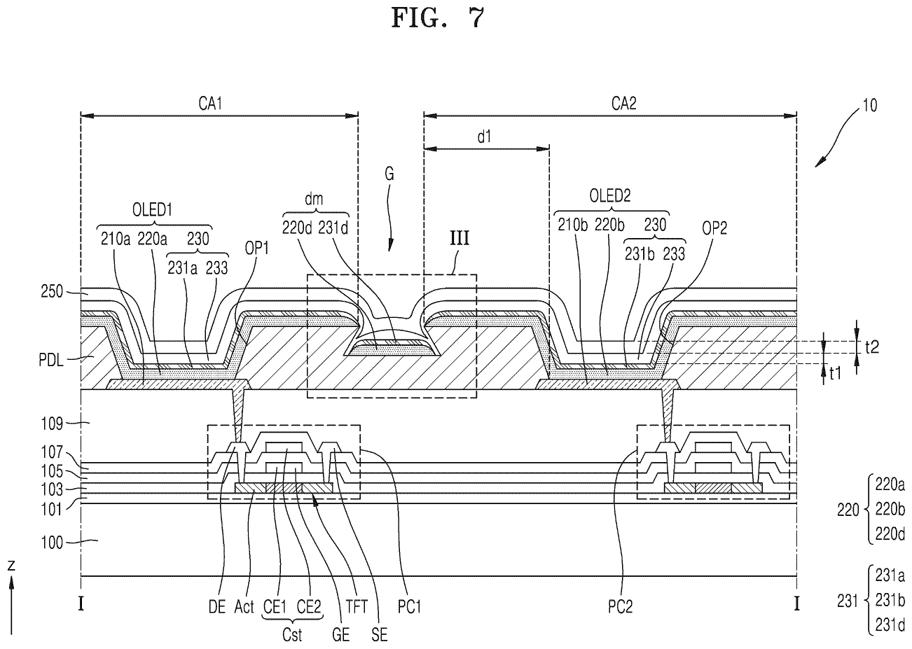

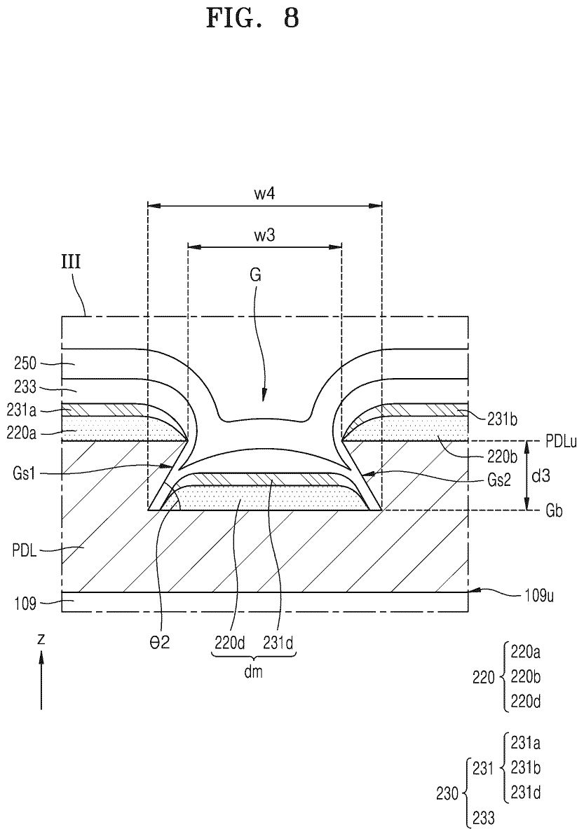

FIG. 7 is a cross-sectional view schematically illustrating a display panel according to an embodiment. FIG. 8 is a cross-sectional view schematically illustrating a groove according to an embodiment.

FIG. 8 is an enlarged view of the region III of FIG. 7. FIGS. 7 and 8 illustrate that the separator SP includes (e.g., is) a groove G defined by the pixel-defining layer PDL.

Referring to FIGS. 7 and 8 together, the buffer layer 101 may be arranged on the substrate 100, and the first pixel circuit PC1 and the second pixel circuit PC2 may be arranged on the buffer layer 101. The planarization layer 109 may be arranged on the first pixel circuit PC1 and the second pixel circuit PC2, and the first organic light-emitting diode OLED1 and the second organic light-emitting diode OLED2 may be arranged on the planarization layer 109. The first organic light-emitting diode OLED1 may be electrically connected to the first pixel circuit PC1, and the second organic light-emitting diode OLED2 may be electrically connected to the second pixel circuit PC2.

The first organic light-emitting diode OLED1 may include the first pixel electrode 210a, the first intermediate layer 220a, and the opposite electrode 230. The opposite electrode 230 of the first organic light-emitting diode OLED1 may include the first-first conductive layer 231a and the second conductive layer 233. The second organic light-emitting diode OLED2 may include the second pixel electrode 210b, the second intermediate layer 220b, and the opposite electrode 230. The opposite electrode 230 of the second organic light-emitting diode OLED2 may include the first-second conductive layer 231b and the second conductive layer 233.

The pixel-defining layer PDL may be arranged to cover the edge of each of the first pixel electrode 210a and the second pixel electrode 210b. The pixel-defining layer PDL may define the first pixel opening OP1 exposing a portion of the first pixel electrode 210a, the second pixel opening OP2 exposing a portion of the second pixel electrode 210b, and the groove G surrounding (e.g., around a periphery of) each of the first pixel opening OP1 and the second pixel opening OP2. In an embodiment, the groove G may completely surround (e.g., around a periphery of) each of the first pixel opening OP1 and the second pixel opening OP2. In another embodiment, the groove G may surround (e.g., around a periphery of) each of the first pixel opening OP1 and the second pixel opening OP2, but may have at least one side that is open.

The groove G may be formed by removing a portion of the pixel-defining layer PDL. The groove G may have an undercut shape or eaves shape, where the top surface PDLu of the pixel-defining layer PDL protrudes in a direction toward the center of the groove G. In other words, as shown in FIG. 8, a width w3 of the groove G in the top surface PDLu of the pixel-defining layer PDL may be smaller than a width w4 of a bottom surface Gb of the groove G.

The groove G may have a first side surface Gs1 and a second side surface Gs2, which face each other. The first side surface Gs1 of the groove G may be inclined by a second angle θ2 with respect to the top surface of the substrate 100. In an embodiment, the second angle θ2 may be about 40° to about 50°. When the second angle θ2 is less than 40°, the thickness of the opposite electrode 230 may be excessively decreased at the first side surface Gs1 and the second side surface Gs2 of the groove G or the opposite electrode 230 may be cut off, and thus, the organic light-emitting diodes may not emit light. When the second angle θ2 is greater than 50°, the intermediate layer 220 may not be completely cut off by the groove G and may remain connected, and thus, a leakage current may flow between adjacent organic light-emitting diodes.

The bottom surface Gb of the groove G may be spaced apart by a third distance d3 from the top surface PDLu of the pixel-defining layer PDL. The third distance d3 may be greater than or equal to about 1.1 μm. When the third distance d3 is less than 1.1 μm, the intermediate layer 220 may not be completely cut off by the groove G and may remain connected. FIGS. 7 and 8 illustrate that the bottom surface Gb of the groove G is spaced apart from a top surface 109u of the planarization layer 109 in the third direction (e.g., the z direction or a thickness direction), but the disclosure is not limited thereto. In another embodiment, the groove G may penetrate the pixel-defining layer PDL, such that the top surface 109u of the planarization layer 109 may be exposed by the groove G and may form the bottom surface Gb of the groove G.

The intermediate layer 220 may be arranged on the pixel-defining layer PDL. The intermediate layer 220 may include the first intermediate layer 220a arranged in the first region CA1, the second intermediate layer 220b arranged in the second region CA2, and the dummy intermediate layer 220d arranged on the bottom surface Gb of the groove G.

The intermediate layer 220 may include a plurality of emitting units (e.g., a plurality of emitting layers or stacks), and the charge generation layer CGL arranged between the emitting units, as described above with reference to FIG. 3. The intermediate layer 220 may be divided into the first intermediate layer 220a, the second intermediate layer 220b, and a dummy intermediate layer 220d by the groove G having the undercut shape. A material for forming the intermediate layer 220 may have a low step coverage, and thus, may not be deposited on the first side surface Gs1 and the second side surface Gs2 of the groove G, or may be divided without being connected even when deposited on a portion of each of the first side surface Gs1 and the second side surface Gs2 of the groove G. In other words, the first intermediate layer 220a may be cut off by the first side surface Gs1 of the groove G, and the second intermediate layer 220b may be cut off by the second side surface Gs2 of the groove G. The dummy intermediate layer 220d may be arranged on the bottom surface Gb of the groove G, and may be spaced apart from the first intermediate layer 220a and the second intermediate layer 220b in the third direction (e.g., the z direction).

The opposite electrode 230 may be arranged on the intermediate layer 220. The opposite electrode 230 may include the first conductive layer 231 and the second conductive layer 233. The first conductive layer 231 may be divided into the first-first conductive layer 231a arranged in the first region CA1, the first-second conductive layer 231b arranged in the second region CA2, and a dummy conductive layer 231d arranged on the bottom surface Gb of the groove G by the groove G having the undercut shape. The first-first conductive layer 231a may be cut off by the first side surface Gs1 of the groove G, and the first-second conductive layer 231b may be cut off by the second side surface Gs2 of the groove G. The dummy conductive layer 231d may be arranged on the bottom surface Gb of the groove G, and may be spaced apart from the first-first conductive layer 231a and the first-second conductive layer 231b in the third direction (e.g., the z direction).

The second conductive layer 233 has a relatively high step coverage, and thus, may extend to cover the first side surface Gs1, the bottom surface Gb, and the second side surface Gs2 of the groove G. In other words, the second conductive layer 233 may be commonly provided in the first organic light-emitting diode OLED1 and the second organic light-emitting diode OLED2.

The capping layer 250 may be arranged on the opposite electrode 230. In an embodiment, on the first pixel electrode 210a and the second pixel electrode 210b, the sum of the thickness t1 of the second conductive layer 233 of the opposite electrode 230 and the thickness t2 of the capping layer 250 may be about 1,200 Å. The thickness t1 of the second conductive layer 233 may be about 100 Å to about 900 Å. The thickness t2 of the capping layer 250 may be about 300 Å to about 1,100 Å.

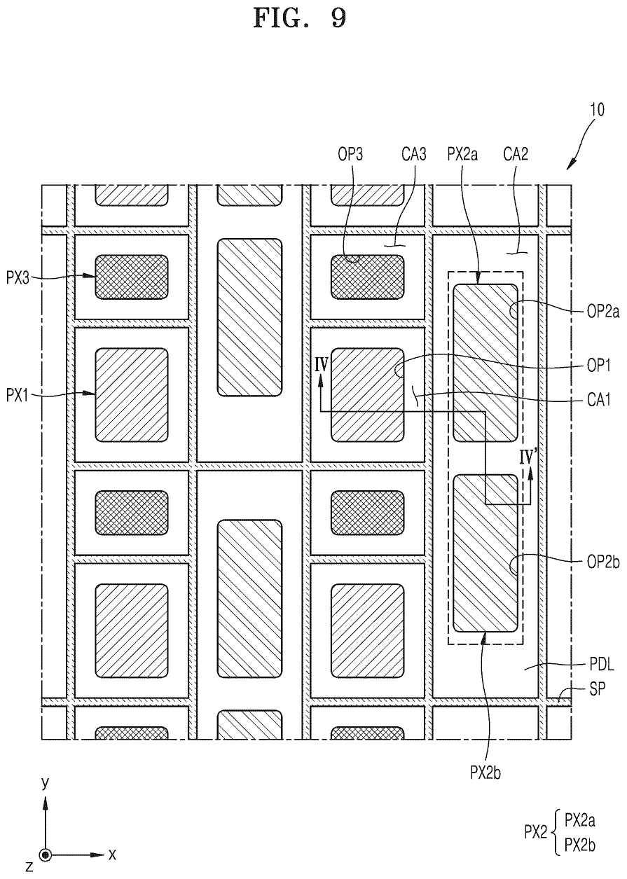

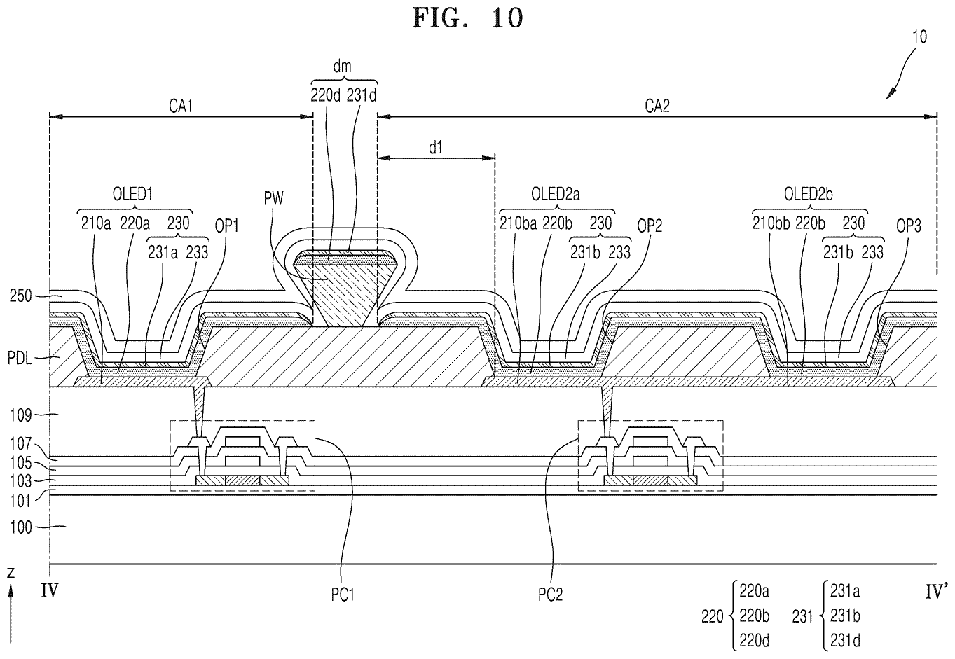

FIG. 9 is a plan view schematically illustrating a display panel according to an embodiment. FIG. 10 is a cross-sectional view schematically illustrating a display panel according to an embodiment.

FIG. 9 illustrates the pixels PX1, PX2, and PX3, the pixel-defining layer PDL, and the separator SP, which are arranged on the display panel 10. FIG. 10 schematically illustrates a cross-section of the display panel 10 taken along the line IV-IV′ shown in FIG. 9. FIG. 10 illustrates that the separator SP includes (e.g., is) the partition wall PW of which a cross-section has the reverse tapered shape, but the present disclosure is not limited thereto. In another embodiment, as described above with reference to FIG. 8, the separator SP may include (e.g., may be) the groove G defined by the pixel-defining layer PDL.

Referring to FIG. 9, the pixels PX1, PX2, and PX3 may be arranged in the display region DA of the display panel 10. The pixels PX1, PX2, and PX3 may include the first pixel PX1 that emits green light, the second pixel PX2 that emits blue light, and the third pixel PX3 that emits red light. In an embodiment, each of the first pixel PX1, the second pixel PX2, and the third pixel PX3 may emit white light.

The first pixel PX1, the second pixel PX2, and the third pixel PX3 may be arranged according to a suitable rule (e.g., a certain or predetermined rule), such as a stripe arrangement or a diamond shape arrangement (e.g., a PENTILE® arrangement, PENTILE® being a duly registered trademark of Samsung Display Co., Ltd.). In an embodiment, the third pixel PX3 and the first pixel PX1 may be arranged alternately in the second direction (e.g., the y direction), and the second pixel PX2 may be spaced apart from the third pixel PX3 and the first pixel PX1 in the first direction (e.g., the x direction). The second pixel PX2 may include a pair of a second-first pixel PX2a and a second-second pixel PX2b, which are adjacent to each other in the second direction (e.g., the y direction).

As shown in FIG. 10, the second-first pixel PX2a may include a second-first organic light-emitting diode OLED2a, and the second-second pixel PX2b may include a second-second organic light-emitting diode OLED2b. The second-first organic light-emitting diode OLED2a may include a second-first pixel electrode 210ba, the second intermediate layer 220b, and the opposite electrode 230. The second-second organic light-emitting diode OLED2b may include a second-second pixel electrode 210bb, the second intermediate layer 220b, and the opposite electrode 230. The second-first pixel electrode 210ba and the second-second pixel electrode 210bb may be connected to the second pixel circuit PC2. Therefore, the second-first organic light-emitting diode OLED2a and the second-second organic light-emitting diode OLED2b may concurrently (e.g., simultaneously or substantially simultaneously) emit light with each other according to the same scan signal and the same data signal. In an embodiment, the second-first pixel electrode 210ba and the second-second pixel electrode 210bb may be connected to each other through a connection wire or the like. In another embodiment, the second-first pixel electrode 210ba and the second-second pixel electrode 210bb may be integrally provided with each other as a single body.

The pixel-defining layer PDL may define the first pixel opening OP1, a second-first pixel opening OP2a, a second-second pixel opening OP2b, and the third pixel opening OP3. The pixel-defining layer PDL may define an emission region of each of the pixels PX1, PX2a, PX2b, and PX3 through the pixel openings OP1, OP2a, OP2b, and OP3. For example, the emission region of the first pixel PX1 may be defined by the first pixel opening OP1, the emission region of the second-first pixel PX2a may be defined by the second-first pixel opening OP2a, the emission region of the second-second pixel PX2b may be defined by the second-second pixel opening OP2b, and the emission region of the third pixel PX3 may be defined by the third pixel opening OP3. A distance between the second-first pixel opening OP2a and the second-second pixel opening OP2b, which form a pair, may be smaller than a distance between the second-second pixel opening OP2b of the pair and the second-first pixel opening OP2a of another adjacent pair.

The display panel 10 may include the separator SP. In an embodiment, as shown in FIG. 10, the separator SP may include (e.g., may be) the partition wall PW arranged on the pixel-defining layer PDL. A cross-section of the partition wall PW may have the reverse tapered shape.

In an embodiment, the separator SP may have a mesh structure having a plurality of cells having a closed shape in a plan view. The first pixel PX1, the second pixel PX2, or a pair of the second-first pixel PX2a and the second-second pixel PX2b, may be arranged in each of the plurality of cells. For example, the first pixel PX1 may be arranged in the first region CA1 defined by the first cell, the second-first pixel PX2a and the second-second pixel PX2b may be arranged in the second region CA2 defined by the second cell, and the third pixel PX3 may be arranged in the third region CA3 defined by the third cell. The separator SP may be arranged to completely surround (e.g., around a periphery of) each of the first pixel opening OP1 and the third pixel opening OP3, in a plan view. The separator SP may be arranged to completely surround (e.g., around a periphery of) a pair of the second-first pixel opening OP2a and the second-second pixel opening OP2b, in a plan view.

In another embodiment, the separator SP may surround (e.g., around a periphery of) each of the first pixel opening OP1, the second-first pixel opening OP2a and the second-second pixel opening OP2b, and the third pixel opening OP3, in a plan view, and may have at least one side that is open. For example, the plurality of cells defined by the separator SP may have at least one side that is open, and thus, may be connected to each other.

The separator SP may cut off and divide at least a portion of the intermediate layer 220 arranged in each of the first region CA1, the second region CA2, and the third region CA3 to prevent or reduce, between adjacent pixels, a leakage current from flowing through the intermediate layer 220. For example, as shown in FIG. 10, the intermediate layer 220 may include the first intermediate layer 220a arranged in the first region CA1, the second intermediate layer 220b arranged in the second region CA2, and the dummy intermediate layer 220d arranged on the top surface PWu of the partition wall PW. The first intermediate layer 220a may be cut off by the first side surface PWs1 of the partition wall PW, and the second intermediate layer 220b may be cut off by the second side surface PWs2 of the partition wall PW. The dummy intermediate layer 220d may be arranged on the top surface PWu of the partition wall PW, and may be spaced apart from the first intermediate layer 220a and the second intermediate layer 220b in the third direction (e.g., the z direction).

The opposite electrode 230 may be arranged on the intermediate layer 220. The opposite electrode 230 may include the first conductive layer 231 and the second conductive layer 233. The separator SP may cut off and divide the first conductive layer 231 arranged in each of the first region CA1 and the second region CA2. For example, the first conductive layer 231 may include the first-first conductive layer 231a arranged in the first region CA1, the first-second conductive layer 231b arranged in the second region CA2, and the dummy conductive layer 231d arranged on the top surface PWu of the partition wall PW. The first-first conductive layer 231a may be cut off by the first side surface PWs1 of the partition wall PW, and the first-second conductive layer 231b may be cut off by the second side surface PWs2 of the partition wall PW. The dummy conductive layer 231d may be arranged on the top surface PWu of the partition wall PW, and may be spaced apart from the first-first conductive layer 231a and the first-second conductive layer 231b in the third direction (e.g., the z direction).

In the present embodiment, because the separator SP is not arranged between the second-first organic light-emitting diode OLED2a and the second-second organic light-emitting diode OLED2b, the second intermediate layer 220b and the first-second conductive layer 231b may be commonly provided in the second-first organic light-emitting diode OLED2a and the second-second organic light-emitting diode OLED2b.

The second conductive layer 233 may not be broken by the separator SP, and may be integrally provided as a single body on the entire or substantially the entire surface of the display region DA. The second conductive layer 233 may be commonly provided in the first organic light-emitting diode OLED1, the second-first organic light-emitting diode OLED2a, and the second-second organic light-emitting diode OLED2b. The capping layer 250 may be arranged on the opposite electrode 230.

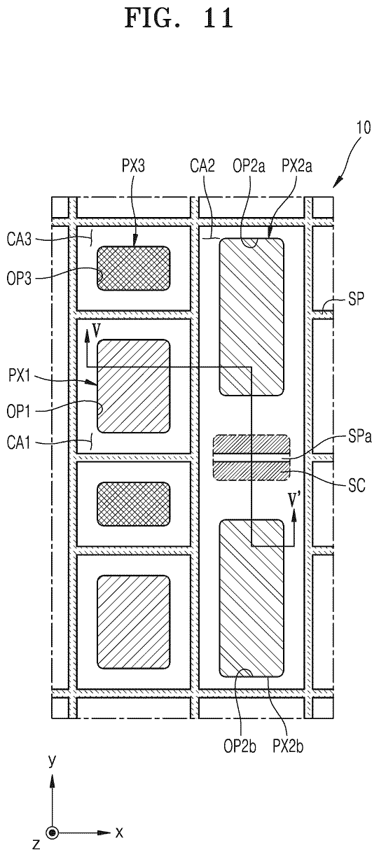

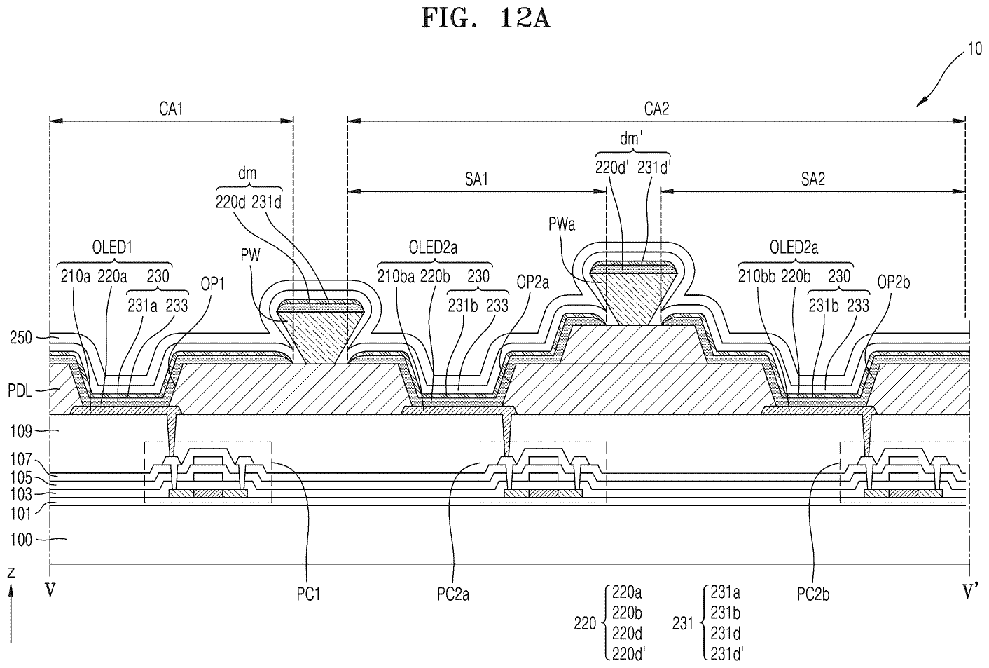

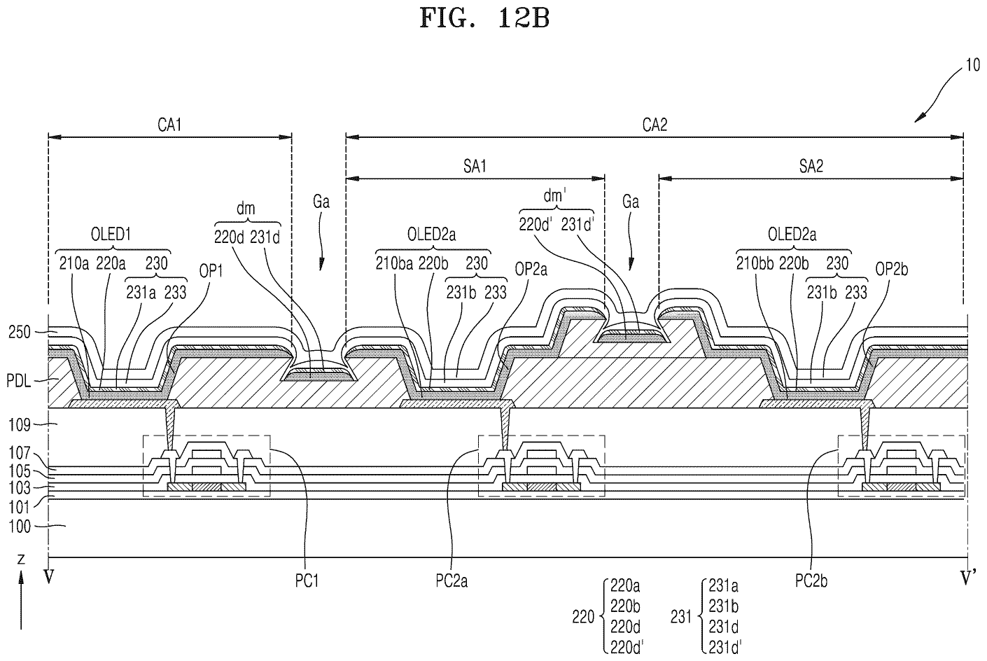

FIG. 11 is a plan view schematically illustrating a display panel according to an embodiment. FIG. 12A is a cross-sectional view schematically illustrating a display panel according to an embodiment. FIG. 12B is a cross-sectional view schematically illustrating a display panel according to an embodiment.

FIG. 11 illustrates that a spacer SC is arranged between the second-first pixel PX2a and the second-second pixel PX2b. FIGS. 12A and 12B each schematically illustrate a cross-section of the display panel 10 taken along the line V-V′ shown in FIG. 11.

Referring to FIG. 11, the pixels PX1, PX2, and PX3 may be arranged in the display region DA of the display panel 10. The pixels PX1, PX2, and PX3 may include the first pixel PX1 that emits green light, the second-first pixel PX2a and the second-second pixel PX2b, which emit blue light, and the third pixel PX3 that emits red light.

The pixel-defining layer PDL may define the pixel openings OP1, OP2a, OP2b, and OP3. The pixel-defining layer PDL may define an emission region of each of the pixels PX1, PX2a, PX2b, and PX3 through the pixel openings OP1, OP2a, OP2b, and OP3. For example, the emission region of the first pixel PX1 may be defined by the first pixel opening OP1, the emission region of the second-first pixel PX2a may be defined by the second-first pixel opening OP2a, the emission region of the second-second pixel PX2b may be defined by the second-second pixel opening OP2b, and the emission region of the third pixel PX3 may be defined by the third pixel opening OP3.

The display panel 10 may include the separator SP. In an embodiment, as shown in FIG. 12A, the separator SP may include (e.g., may be) the partition wall PW arranged on the pixel-defining layer PDL and having a cross-section that has the reverse tapered shape. In another embodiment, the separator SP may include (e.g., may be) the groove G defined by the pixel-defining layer PDL, as shown in FIG. 12B. The groove G may have the undercut shape.

The separator SP may define a plurality of cells having a closed shape in a plan view. The first pixel PX1, the second pixel PX2, or a pair of the second-first pixel PX2a and the second-second pixel PX2b, may be arranged in each of the plurality of cells. For example, the first pixel PX1 may be arranged in the first region CA1 defined by the first cell, the second-first pixel PX2a and the second-second pixel PX2b may be arranged in the second region CA2 defined by the second cell, and the third pixel PX3 may be arranged in the third region CA3 defined by the third cell. The separator SP may be arranged to completely surround (e.g., around a periphery of) each of the first pixel opening OP1 and the third pixel opening OP3, in a plan view. In addition, the separator SP may be arranged to completely surround (e.g., around a periphery of) a pair of the second-first pixel opening OP2a and the second-second pixel opening OP2b, in a plan view.

In another embodiment, the separator SP may surround (e.g., around a periphery of) each of the first pixel opening OP1, the second-first pixel opening OP2a and the second-second pixel opening OP2b, and the third pixel opening OP3, in a plan view, and may have at least one side that is open. For example, the plurality of cells defined by the separator SP may have at least one side that is open, and thus, may be connected to each other.

In an embodiment, the spacer SC may be arranged between the second-first pixel PX2a and the second-second pixel PX2b. The spacer SC may be arranged on the pixel-defining layer PDL, and may protrude from an upper portion of the pixel-defining layer PDL, thereby preventing or substantially preventing the pixels PX1, PX2a, PX2b, and PX3 from being damaged by a mask and the like. In an embodiment, the spacer SC may be integrally provided as a single body with the pixel-defining layer PDL. For example, by using a halftone mask, the spacer SC and the pixel-defining layer PDL may be concurrently (e.g., simultaneously or substantially simultaneously) formed with each other.

In an embodiment, an auxiliary separator SPa may be arranged between the second-first pixel PX2a and the second-second pixel PX2b to overlap with the spacer SC. The auxiliary separator SPa may extend in the first direction (e.g., the x direction). In an embodiment, as shown in FIG. 12A, the auxiliary separator SPa may include (e.g., may be) an auxiliary partition wall PWa arranged directly on the spacer SC. In another embodiment, as shown in FIG. 12B, the auxiliary separator SPa may include (e.g., may be) an auxiliary groove Ga defined by the spacer SC. FIG. 11 illustrates that the auxiliary separator SPa is partially spaced apart from the separator SP, but the present disclosure is not limited thereto. In another embodiment, the auxiliary separator SPa may be connected to the separator SP to completely separate the second-first pixel PX2a and the second-second pixel PX2b from each other.

Referring to FIG. 12A, the buffer layer 101 may be arranged on the substrate 100, and the first pixel circuit PC1, a second-first pixel circuit PC2a, and a second-second pixel circuit PC2b may be arranged on the buffer layer 101. The planarization layer 109 may be arranged on the first pixel circuit PC1, the second-first pixel circuit PC2a, and the second-second pixel circuit PC2b, and the first organic light-emitting diode OLED1, the second-first organic light-emitting diode OLED2a, and the second-second organic light-emitting diode OLED2b may be arranged on the planarization layer 109.

The first organic light-emitting diode OLED1 may include the first pixel electrode 210a, the first intermediate layer 220a, and the opposite electrode 230. The second-first organic light-emitting diode OLED2a may include the second-first pixel electrode 210ba, the second intermediate layer 220b, and the opposite electrode 230. The second-second organic light-emitting diode OLED2b may include the second-second pixel electrode 210bb, the second intermediate layer 220b, and the opposite electrode 230. In an embodiment, the first pixel electrode 210a may be connected to the first pixel circuit PC1, the second-first pixel electrode 210ba may be connected to the second-first pixel circuit PC2a, and the second-second pixel electrode 210bb may be connected to the second-second pixel circuit PC2b.

The pixel-defining layer PDL may define the pixel openings OP1, OP2a, and OP2b. The pixel-defining layer PDL may define an emission region of the pixels PX1, PX2a, and PX2b through the pixel openings OP1, OP2a, and OP2b. As the separator SP, the partition wall PW may be arranged on the pixel-defining layer PDL, and may completely surround (e.g., around a periphery of) the first pixel opening OP1. In addition, the partition wall PW may completely surround (e.g., around a periphery of) the second-first pixel opening OP2a and the second-second pixel opening OP2b.

The intermediate layer 220 may be arranged on the pixel-defining layer PDL, the partition wall PW, the spacer SC, and the auxiliary partition wall PWa. By the partition wall PW and the auxiliary partition wall PWa, the intermediate layer 220 may be divided into the first intermediate layer 220a arranged in the first region CA1, the second intermediate layer 220b arranged in the second region CA2, the dummy intermediate layer 220d arranged on a top surface of the partition wall PW, and a dummy intermediate layer 220d′ arranged on a top surface of the auxiliary partition wall PWa.

The spacer SC may be arranged between the second-first pixel opening OP2a and the second-second pixel opening OP2b. The spacer SC may be arranged on the pixel-defining layer PDL. The auxiliary partition wall PWa may be arranged on the spacer SC. A cross-section of the auxiliary partition wall PWa may have the reverse tapered shape. The auxiliary partition wall PWa may cut off and divide the second intermediate layer 220b, between the second-first organic light-emitting diode OLED2a and the second-second organic light-emitting diode OLED2b.

For convenience of illustration, with respect to the auxiliary partition wall PWa, the second region CA2 may be represented as a first sub-region SA1 in which the second-first pixel opening OP2a is arranged, and a second sub-region SA2 in which the second-second pixel opening OP2b is arranged. A portion of the second intermediate layer 220b, which is arranged in the first sub-region SA1, may be cut off by a first side wall of the auxiliary partition wall PWa, and a portion of the second intermediate layer 220b, which is arranged in the second sub-region SA2, may be cut off by a second side wall of the auxiliary partition wall PWa. The dummy intermediate layer 220d′ arranged on the top surface of the auxiliary partition wall PWa may be spaced apart from the second intermediate layer 220b in the third direction (e.g., the z direction).

The opposite electrode 230 may be arranged on the intermediate layer 220. The opposite electrode 230 may include the first conductive layer 231 and the second conductive layer 233. By the partition wall PW and the auxiliary partition wall PWa, the first conductive layer 231 may be divided into the first-first conductive layer 231a arranged in the first region CA1, the first-second conductive layer 231b arranged in the second region CA2, the dummy conductive layer 231d arranged on the top surface of the partition wall PW, and a dummy conductive layer 231d′ arranged on the top surface of the auxiliary partition wall PWa.

The auxiliary partition wall PWa may cut off and divide the first-second conductive layer 231b, between the second-first organic light-emitting diode OLED2a and the second-second organic light-emitting diode OLED2b. A portion of the first-second conductive layer 231b, which is arranged in the first sub-region SA1, may be cut off by the first side wall of the auxiliary partition wall PWa, and a portion of the first-second conductive layer 231b, which is arranged in the second sub-region SA2, may be cut off by the second side wall of the auxiliary partition wall PWa. The dummy conductive layer 231d′ arranged on the top surface of the auxiliary partition wall PWa may be spaced apart from the adjacent first-second conductive layer 231b in the third direction (e.g., the z direction).

The second conductive layer 233 may not be broken by the partition wall PW and the auxiliary partition wall PWa, and may be integrally provided as a single body throughout the display region DA. The second conductive layer 233 may be commonly provided in the first organic light-emitting diode OLED1, the second-first organic light-emitting diode OLED2a, and the second-second organic light-emitting diode OLED2b. The capping layer 250 may be arranged on the opposite electrode 230.

FIG. 12B is similar to FIG. 12A, but differs from FIG. 12A in that the groove G is provided as the separator SP, and the auxiliary groove Ga is provided as the auxiliary separator SPa. The auxiliary groove Ga may be defined by the spacer SC. In other words, the auxiliary groove Ga may be formed by removing a portion of the spacer SC. The auxiliary groove Ga may have the undercut shape or eaves shape, where a top surface of the spacer SC protrudes in a direction toward the center of the auxiliary groove Ga.

By the groove G and the auxiliary groove Ga, the intermediate layer 220 may be divided into the first intermediate layer 220a arranged in the first region CA1, the second intermediate layer 220b arranged in the second region CA2, the dummy intermediate layer 220d arranged on a bottom surface of the groove G, and the dummy intermediate layer 220d′ arranged on a bottom surface of the auxiliary groove Ga.

The auxiliary groove Ga may cut off and divide the second intermediate layer 220b, between the second-first organic light-emitting diode OLED2a and the second-second organic light-emitting diode OLED2b. A portion of the second intermediate layer 220b, which is arranged in the first sub-region SA1, may be cut off by a first side wall of the auxiliary groove Ga, and a portion of the second intermediate layer 220b, which is arranged in the second sub-region SA2, may be cut off by second side wall of the auxiliary groove Ga. The dummy intermediate layer 220d′ arranged on the bottom surface of the auxiliary groove Ga may be spaced apart from the second intermediate layer 220b in the third direction (e.g., the z direction).

The opposite electrode 230 may include the first conductive layer 231 and the second conductive layer 233. By the groove G and the auxiliary groove Ga, the first conductive layer 231 may be divided into the first-first conductive layer 231a arranged in the first region CA1, the first-second conductive layer 231b arranged in the second region CA2, the dummy conductive layer 231d arranged on the bottom surface of the groove G, and the dummy conductive layer 231d′ arranged on the bottom surface of the auxiliary groove Ga.

The auxiliary groove Ga may cut off and divide the first-second conductive layer 231b, between the second-first organic light-emitting diode OLED2a and the second-second organic light-emitting diode OLED2b. A portion of the first-second conductive layer 231b, which is arranged in the first sub-region SA1, may be cut off by the first side wall of the auxiliary groove Ga, and a portion of the first-second conductive layer 231b, which is arranged in the second sub-region SA2, may be cut off by the second side wall of the auxiliary groove Ga. The dummy conductive layer 231d arranged on the bottom surface of the auxiliary groove Ga may be spaced apart from the adjacent first-second conductive layer 231b in the third direction (e.g., the z direction).

The second conductive layer 233 may not be broken by the groove G and the auxiliary groove Ga, and may be integrally provided as a single body throughout the display region DA. The second conductive layer 233 may be commonly provided in the first organic light-emitting diode OLED1, the second-first organic light-emitting diode OLED2a, and the second-second organic light-emitting diode OLED2b. The capping layer 250 may be arranged on the opposite electrode 230.

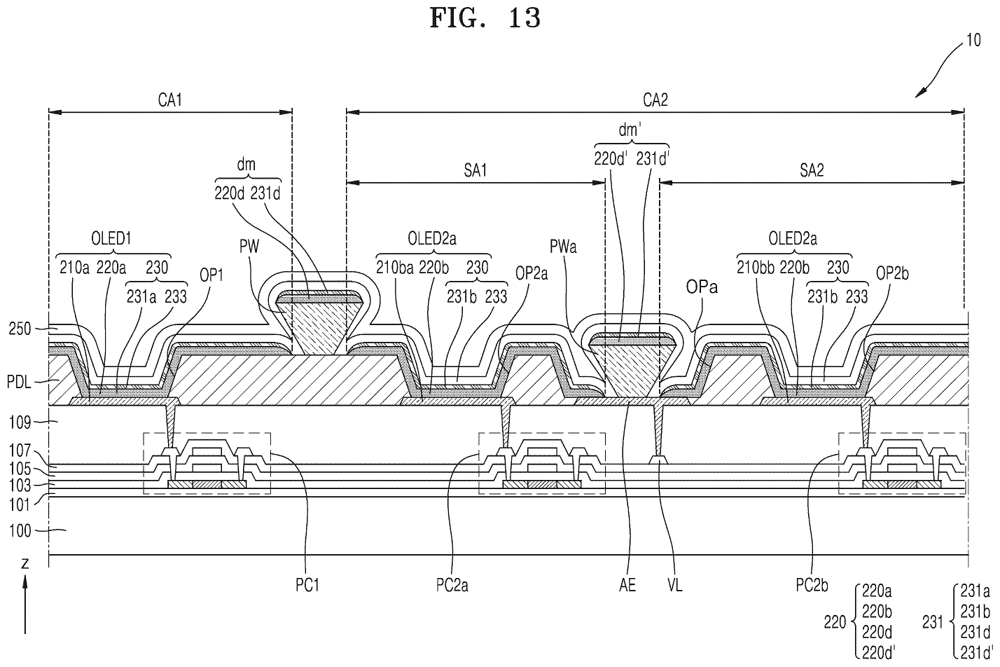

FIG. 13 is a cross-sectional view schematically illustrating a display panel according to an embodiment.

FIG. 13 is similar to FIG. 12A, but illustrates in place of the spacer SC, an auxiliary electrode AE and an auxiliary opening OPa exposing a portion of the auxiliary electrode AE that are arranged between the second-first pixel opening OP2a and the second-second pixel opening OP2b. The auxiliary partition wall PWa may be arranged on the auxiliary electrode AE.

Referring to FIG. 13, the buffer layer 101 may be arranged on the substrate 100, and the first pixel circuit PC1, the second-first pixel circuit PC2a, and the second-second pixel circuit PC2b may be arranged on the buffer layer 101. The planarization layer 109 may be arranged on the first pixel circuit PC1, the second-first pixel circuit PC2a, and the second-second pixel circuit PC2b, and the first organic light-emitting diode OLED1, the second-first organic light-emitting diode OLED2a, and the second-second organic light-emitting diode OLED2b may be arranged on the planarization layer 109.

The first organic light-emitting diode OLED1 may include the first pixel electrode 210a, the first intermediate layer 220a, and the opposite electrode 230. The second-first organic light-emitting diode OLED2a may include a second-first pixel electrode 210ba, the second intermediate layer 220b, and the opposite electrode 230. The second-second organic light-emitting diode OLED2b may include a second-second pixel electrode 210bb, the second intermediate layer 220b, and the opposite electrode 230. In an embodiment, the first pixel electrode 210a may be connected to the first pixel circuit PC1, the second-first pixel electrode 210ba may be connected to the second-first pixel circuit PC2a, and the second-second pixel electrode 210bb may be connected to the second-second pixel circuit PC2b.

In an embodiment, the auxiliary electrode AE may be arranged between the planarization layer 109 and the pixel-defining layer PDL. The auxiliary electrode AE may be arranged at (e.g., in or on) the same layer as that of the first pixel electrode 210a, the second-first pixel electrode 210ba, and the second-second pixel electrode 210bb, and may include the same material as each other. The auxiliary electrode AE may be connected to a voltage line VL configured to transmit the common voltage ELVSS, through a contact hole penetrating the planarization layer 109.

The pixel-defining layer PDL may define the pixel openings OP1, OP2a, and OP2b, and the auxiliary opening OPa exposing a portion of the auxiliary electrode AE. As the separator SP, the partition wall PW may be arranged on the pixel-defining layer PDL, and may completely surround (e.g., around a periphery of) the first pixel opening OP1. In addition, the partition wall PW may completely surround (e.g., around a periphery of) the second-first pixel opening OP2a and the second-second pixel opening OP2b. In other words, in a plan view, the second-first pixel opening OP2a and the second-second pixel opening OP2b may be arranged in the second cell defined by the partition wall PW.

As the auxiliary separator SPa, the auxiliary partition wall PWa may be arranged on the auxiliary electrode AE. The auxiliary partition wall PWa may be arranged in the auxiliary opening OPa. A cross-section of the auxiliary partition wall PWa may have the reverse tapered shape.

The intermediate layer 220 may be arranged on the pixel-defining layer PDL, the partition wall PW, and the auxiliary partition wall PWa. By the partition wall PW and the auxiliary partition wall PWa, the intermediate layer 220 may be divided into the first intermediate layer 220a arranged in the first region CA1, the second intermediate layer 220b arranged in the second region CA2, the dummy intermediate layer 220d arranged on a top surface of the partition wall PW, and a dummy intermediate layer 220d′ arranged on a top surface of the auxiliary partition wall PWa. The auxiliary partition wall PWa may cut off and divide the second intermediate layer 220b, between the second-first organic light-emitting diode OLED2a and the second-second organic light-emitting diode OLED2b. In a plan view, a portion of the auxiliary electrode AE, which overlaps with the top surface of the auxiliary partition wall PWa, may be exposed from the intermediate layer 220.

The opposite electrode 230 may be arranged on the intermediate layer 220. The opposite electrode 230 may include the first conductive layer 231 and the second conductive layer 233. By the partition wall PW and the auxiliary partition wall PWa, the first conductive layer 231 may be divided into the first-first conductive layer 231a arranged in the first region CA1, the first-second conductive layer 231b arranged in the second region CA2, the dummy conductive layer 231d arranged on the top surface of the partition wall PW, and a dummy conductive layer 231d′ arranged on the top surface of the auxiliary partition wall PWa. The auxiliary partition wall PWa may cut off and divide the first-second conductive layer 231b, between the second-first organic light-emitting diode OLED2a and the second-second organic light-emitting diode OLED2b.

The second conductive layer 233 may not be broken by the partition wall PW and the auxiliary partition wall PWa, and may be integrally provided as a single body throughout the display region DA. The capping layer 250 may be arranged on the opposite electrode 230. The second conductive layer 233 may overlap with the top surface of the auxiliary partition wall PWa, and thus, may be in direct contact with the portion of the auxiliary electrode AE exposed from the intermediate layer 220. Therefore, the second conductive layer 233 may be in direct contact with the auxiliary electrode AE, and thus, may receive the common voltage ELVSS. The second conductive layer 233 may be commonly provided in the first organic light-emitting diode OLED1, the second-first organic light-emitting diode OLED2a, and the second-second organic light-emitting diode OLED2b. Because the second conductive layer 233 receives the common voltage ELVSS from the auxiliary electrode AE, the display panel 10 may have a reduced luminance deviation caused by a voltage drop of the common voltage ELVSS.

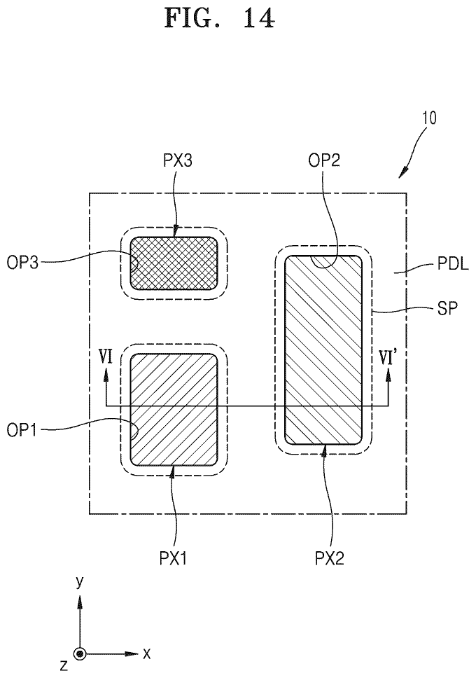

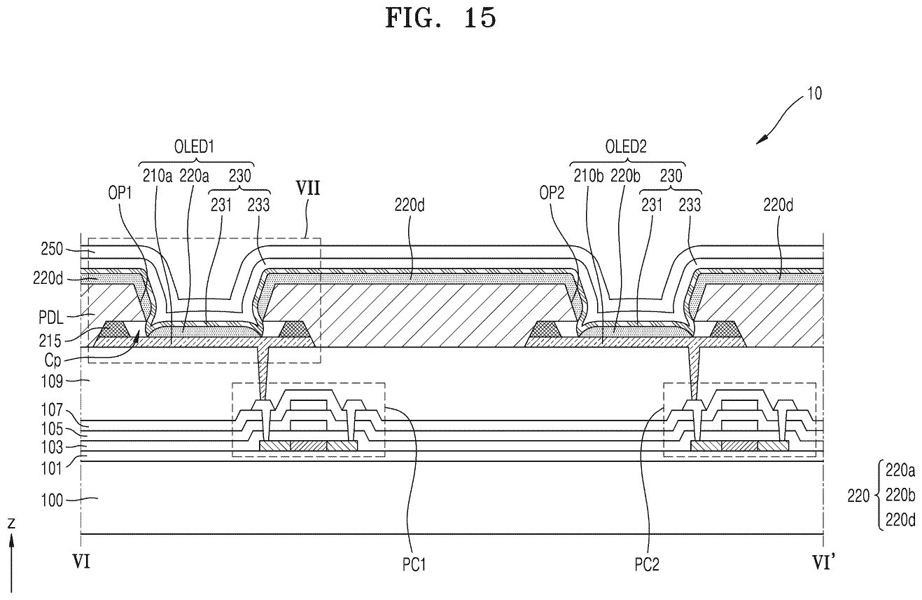

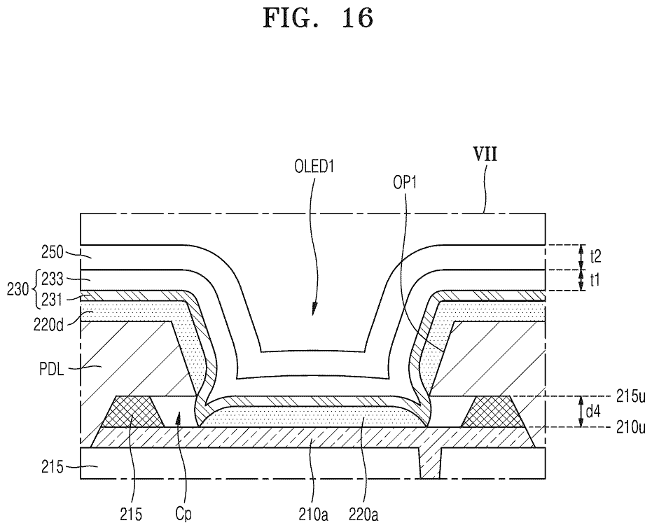

FIG. 14 is a plan view schematically illustrating a display panel according to an embodiment. FIG. 15 is a cross-sectional view schematically illustrating a display panel according to an embodiment. FIG. 16 is a schematic cross-sectional view schematically illustrating an organic light-emitting diode according to an embodiment.

FIG. 14 illustrates the pixels PX1, PX2, and PX3, the pixel-defining layer PDL, and the separator SP, which are arranged in the display region DA of the display panel 10. The pixels PX1, PX2, and PX3 shown in FIG. 14 may represent emission regions of the pixels PX1, PX2, and PX3 defined by the pixel openings OP1, OP2, and OP3 in the pixel-defining layer PDL. FIG. 15 schematically illustrates a cross-section of the display panel 10 taken along the line VI-VI′ shown in FIG. 14. FIG. 16 is an enlarged view of the region VII of FIG. 15.

Referring to FIG. 14, the pixels PX1, PX2, and PX3 may be arranged in the display region DA of the display panel 10. The pixels PX1, PX2, and PX3 may include the first pixel PX1 that emits green light, the second pixel PX2 that emits blue light, and the third pixel PX3 that emits red light.

The pixel-defining layer PDL may define the pixel openings OP1, OP2, and OP3. The pixel-defining layer PDL may define an emission region of each of the pixels PX1, PX2, and PX3 through the pixel openings OP1, OP2, and OP3. For example, the emission region of the first pixel PX1 may be defined by the first pixel opening OP1, the emission region of the second pixel PX2 may be defined by the second pixel opening OP2, and the emission region of the third pixel PX3 may be defined by the third pixel opening OP3.

The display panel 10 may include the separator SP. In an embodiment, the separator SP may be arranged along an edge of each of the pixel openings OP1, OP2, and OP3. For example, the separator SP may include concave portions (e.g., grooves) defined along an inner surface of each of the pixel openings OP1, OP2, and OP3. The concave portions (e.g., grooves) extend along an inner surface of each of the pixel openings OP1, OP2 and OP3 to completely surround (e.g., around a periphery of) a central portion of each of the pixel openings OP1, OP2, and OP3. The separator SP may cut off and divide the intermediate layers 220 arranged inside each of the pixel openings OP1, OP2, and OP3 to reduce, between adjacent pixels, a leakage current through the intermediate layer 220.

Referring to FIG. 15, the display panel 10 may include the substrate 100. The buffer layer 101 may be arranged on the substrate 100, and the first pixel circuit PC1 and the second pixel circuit PC2 may be arranged on the buffer layer 101. The planarization layer 109 may be arranged on the first pixel circuit PC1 and the second pixel circuit PC2, and the first organic light-emitting diode OLED1 and the second organic light-emitting diode OLED2 may be spaced apart from each other on the planarization layer 109.

The first organic light-emitting diode OLED1 may include the first pixel electrode 210a, the first intermediate layer 220a, and the opposite electrode 230. The second organic light-emitting diode OLED2 may include the second pixel electrode 210b, the second intermediate layer 220b, and the opposite electrode 230. The first pixel electrode 210a may be electrically connected to the first pixel circuit PC1 through a contact hole penetrating the planarization layer 109. In other words, the first organic light-emitting diode OLED1 may be electrically connected to the first pixel circuit PC1. Likewise, the second pixel electrode 210b may be electrically connected to the second pixel circuit PC2 through a contact hole penetrating the planarization layer 109.

The pixel-defining layer PDL may be arranged to cover an edge of each of the first pixel electrode 210a and the second pixel electrode 210b. The pixel-defining layer PDL may define the first pixel opening OP1 exposing a portion of the first pixel electrode 210a, and the second pixel opening OP2 exposing a portion of the second pixel electrode 210b.

Referring to FIGS. 15 and 16 together, a concave portion Cp that completely surrounds (e.g., around a periphery of) the central portion of the first pixel opening OP1 may be defined on the inner surface of the first pixel opening OP1. The concave portion Cp may surround around the first pixel electrode 210a, and the second pixel electrode 210b. The concave portion Cp extends along the inner surface of each of the first pixel opening OP1 and the second pixel opening OP2. The concave portion Cp may be formed along a boundary between the pixel-defining layer PDL and an edge of the first pixel electrode 210a, and thus, the pixel-defining layer PDL may have an undercut structure or eaves structure, where an upper portion thereof protrudes in a direction toward the center of the first pixel opening OP1.

In an embodiment, the concave portion Cp may be formed by removing a portion of a sacrificial layer arranged on the first pixel electrode 210a. The sacrificial layer may include a suitable material that may be removed through a wet etching process without damaging the first pixel electrode 210a. For example, the sacrificial layer may include IGZO. In an embodiment, a portion of the sacrificial layer, which is not removed by the etching process, may remain between the pixel-defining layer PDL and the first pixel electrode 210a to form a residual sacrificial layer 215.

Likewise, the concave portion Cp, which completely surrounds (e.g., around a periphery of) the central portion of the second pixel opening OP2, may be defined on the inner surface of the second pixel opening OP2. The concave portion Cp may be formed between the pixel-defining layer PDL and the second pixel electrode 210b, and thus, the pixel-defining layer PDL may have an undercut structure or eaves structure, where an upper portion thereof protrudes in a direction toward the center of the second pixel opening OP2. The residual sacrificial layer 215 may be arranged between the second pixel electrode 210b and the pixel-defining layer PDL. A fourth distance d4 between a top surface 215u of the residual sacrificial layer 215 and a top surface 210u of the pixel electrode 210 may define the height of the concave portion Cp. In an embodiment, the fourth distance d4 may be greater than or equal to about 1.1 μm.

The intermediate layer 220 may be arranged on the pixel-defining layer PDL. The intermediate layer 220 may include the first intermediate layer 220a arranged within the first pixel opening OP1 and on the first pixel electrode 210a, the second intermediate layer 220b arranged within the second pixel opening OP2 and on the second pixel electrode 210b, and the dummy intermediate layer 220d arranged on the pixel-defining layer PDL. The intermediate layer 220 may be divided into the first intermediate layer 220a, the second intermediate layer 220b, and the dummy intermediate layer 220d, by the undercut structure of the pixel-defining layer PDL, thereby reducing, between adjacent pixels, a leakage current through the intermediate layer 220.

The intermediate layer 220 may include a plurality of emitting units (e.g., a plurality of emitting layers or stacks), and the charge generation layer CGL arranged between the emitting units, as described above with reference to FIG. 3. In other words, each of the first organic light-emitting diode OLED1 and the second organic light-emitting diode OLED2 may be referred to as a tandem light-emitting device.

The opposite electrode 230 may be arranged on the intermediate layer 220. The opposite electrode 230 may include the first conductive layer 231 and the second conductive layer 233. The first conductive layer 231 may include silver (Ag) or a silver alloy, and may be formed on the entire or substantially the entire surface of the display region DA through a thermal evaporation process. In an embodiment, as shown in FIG. 15, the first conductive layer 231 may not be broken by the undercut structure of the pixel-defining layer PDL, and may be integrally formed as a single body on the entire or substantially the entire surface of the display region DA. In another embodiment, the first conductive layer 231 may be divided into a first-first conductive layer arranged on the first intermediate layer 220a, a first-second conductive layer arranged on the second intermediate layer 220b, and a dummy conductive layer arranged on the dummy intermediate layer 220d, by the undercut structure of the pixel-defining layer PDL.

The second conductive layer 233 may include a transparent conductive oxide, may not be broken by the undercut structure of the pixel-defining layer PDL, and may be integrally provided as a single body on the entire or substantially the entire surface of the display region DA. The second conductive layer 233 may be commonly provided in the first organic light-emitting diode OLED1 and the second organic light-emitting diode OLED2.

The capping layer 250 may be arranged on the opposite electrode 230. In an embodiment, on a surface approximately parallel to a top surface of the substrate 100, the sum of the thickness t1 of the second conductive layer 233 of the opposite electrode 230 and the thickness t2 of the capping layer 250 may be about 1,200 Å. The thickness t1 of the second conductive layer 233 may be about 100 Å to about 900 Å. The thickness t2 of the capping layer 250 may be about 300 Å to about 1,100 Å.

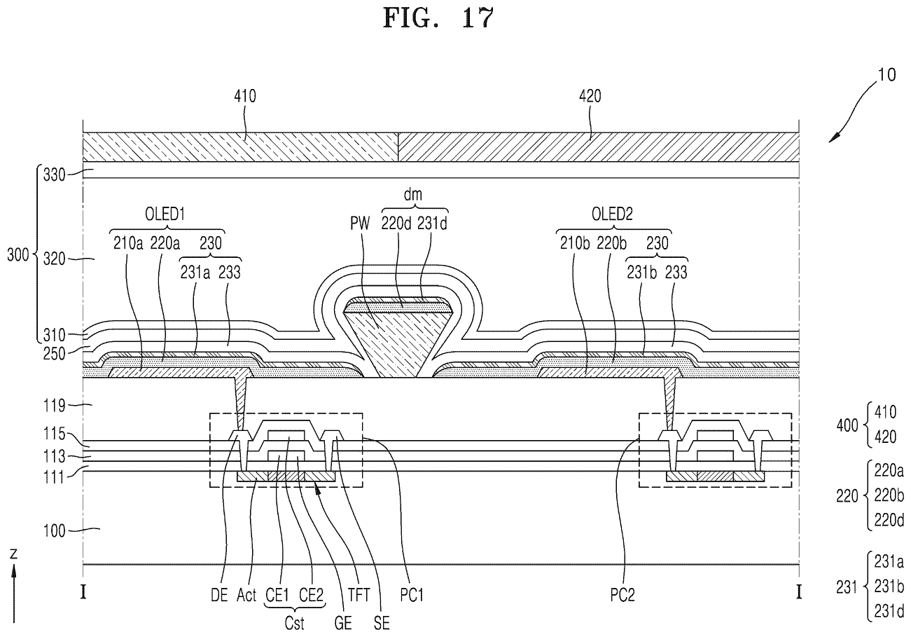

FIG. 17 is a cross-sectional view schematically illustrating a display panel according to an embodiment.

Referring to FIG. 17, the display panel 10 may include the substrate 100. The substrate 100 may include a semiconductor material, for example, such as a Group IV semiconductor, a Group III-V compound semiconductor, or a Group II-VI compound semiconductor. In other words, the substrate 100 may be a semiconductor substrate including a semiconductor material. However, the kind of substrate 100 is not limited to a semiconductor substrate.

The buffer layer 101 may be arranged on the substrate 100. The buffer layer 101 may include an inorganic material, such as silicon oxide, silicon nitride, and/or silicon oxynitride. The first pixel circuit PC1 and the second pixel circuit PC2 may be arranged on the buffer layer 101. The first pixel circuit PC1 and the second pixel circuit PC2 may have the same or similar structures as each other. Hereinafter, for convenience of illustration, the first pixel circuit PC1 may be mainly described in more detail.

The first pixel circuit PC1 may include the thin-film transistor TFT and the capacitor Cst. The thin-film transistor TFT may include the active layer Act, the gate electrode GE, the source electrode SE, and the drain electrode DE.

The active layer Act of the thin-film transistor TFT may be arranged in the substrate 100. The active layer Act may be formed as a portion of the substrate 100. A portion of the substrate 100 may be recessed, and the active layer Act may be arranged on the recessed portion of the substrate 100.

A gate insulating layer 111 may be arranged on the substrate 100. The gate insulating layer 111 may be arranged between the active layer Act and the gate electrode GE. In an embodiment, the gate insulating layer 111 may be patterned to have a shape corresponding to the gate electrode GE, in a plan view.

The gate electrode GE may be arranged on the gate insulating layer 111 to overlap with the active layer Act. The gate electrode GE may include a conductive material, such as molybdenum (Mo), aluminum (AI), copper (Cu), titanium (Ti), indium tin oxide (ITO), or indium zinc oxide (IZO), and may be formed as multilayers or a single layer, each including at least one of the above materials.

A first interlayer insulating layer 113 may be arranged on the gate electrode GE, and the second capacitor electrode CE2 may be arranged on the first interlayer insulating layer 113. At least a portion of the gate electrode GE may overlap with the second capacitor electrode CE2, in a plan view, and may function as the first capacitor electrode CE1 of the capacitor Cst. In other words, the gate electrode GE and the first capacitor electrode CE1 may be integrally provided with each other as a single body. The second capacitor electrode CE2 may include a conductive material, such as molybdenum (Mo), aluminum (AI), copper (Cu), titanium (Ti), indium tin oxide (ITO), or indium zinc oxide (IZO), and may be formed as multilayers or a single layer, each including at least one of the above materials.

A second interlayer insulating layer 115 may be arranged on the second capacitor electrode CE2, and the source electrode SE and the drain electrode DE may be arranged on the second interlayer insulating layer 115. The source electrode SE and the drain electrode DE may each include a conductive material, such as molybdenum (Mo), aluminum (AI), copper (Cu), titanium (Ti), indium tin oxide (ITO), or indium zinc oxide (IZO), and may each be formed as multilayers or a single layer, each including at least one of the above materials. For example, the source electrode SE and the drain electrode DE may each have a multilayered structure of Ti/Al/Ti.

The gate insulating layer 111, the first interlayer insulating layer 113, and the second interlayer insulating layer 115 may each include an inorganic material, such as silicon oxide, silicon nitride, and/or silicon oxynitride, and may each be formed as multilayers or a single layer, each including at least one of the above materials.

A planarization layer 119 may be arranged on the first pixel circuit PC1 and the second pixel circuit PC2. The planarization layer 119 may include an organic insulating material. For example, the planarization layer 119 may include benzocyclobutene (BCB), polyimide, hexamethyldisiloxane (HMDSO), polymethylmethacrylate (PMMA), polystyrene, polymer derivatives with phenolic groups, acryl-based polymers, imide polymers, aryl ether-based polymers, amide-based polymers, fluorine-based polymers, p-xylene-based polymers, vinyl alcohol-based polymers, or suitable mixtures thereof.

The first organic light-emitting diode OLED1 and the second organic light-emitting diode OLED2 may be spaced apart from each other on the planarization layer 119. The first organic light-emitting diode OLED1 and the second organic light-emitting diode OLED2 may emit light of the same color as each other. For example, the first organic light-emitting diode OLED1 and the second organic light-emitting diode OLED2 may each emit white light. A peak spectrum of each of the first organic light-emitting diode OLED1 and the second organic light-emitting diode OLED2 may have peaks in a first wavelength region of about 435 nm to about 490 nm, a second wavelength region of about 500 nm to about 590 nm, and a third wavelength region of about 600 nm to about 710 nm.

The first organic light-emitting diode OLED1 may include the first pixel electrode 210a, the first intermediate layer 220a, and the opposite electrode 230. The opposite electrode 230 of the first organic light-emitting diode OLED1 may include the first-first conductive layer 231a and the second conductive layer 233. The second organic light-emitting diode OLED2 may include the second pixel electrode 210b, the second intermediate layer 220b, and the opposite electrode 230. The opposite electrode 230 of the second organic light-emitting diode OLED2 may include the first-second conductive layer 231b and the second conductive layer 233.

The first pixel electrode 210a may be electrically connected to the first pixel circuit PC1 through a contact hole penetrating the planarization layer 119. Likewise, the second pixel electrode 210b may be electrically connected to the second pixel circuit PC2 through a contact hole penetrating the planarization layer 119.

As the separator SP, the partition wall PW may be arranged on the planarization layer 119. The partition wall PW may be in direct contact with a top surface of the planarization layer 119. In an embodiment, the partition wall PW may include an organic insulating material. In an embodiment, the partition wall PW may include a negative photoresist material of which a solubility with respect to a developer is reduced by exposure. In another embodiment, the partition wall PW may have a multilayered structure of an organic insulating material layer and an inorganic insulating material layer. In another embodiment, the partition wall PW may include an inorganic insulating material.

A cross-section of the partition wall PW may have the reverse tapered shape. For example, as shown in FIG. 17, the width of a top surface of the partition wall PW may be greater than the width of a bottom surface of the partition wall PW. Side surfaces of the partition wall PW may be inclined at an angle of about 130° to about 140° with respect to the top surface of the planarization layer 119. The top surface of the partition wall PW may be spaced apart by about 1.1 μm to about 3 μm from the top surface of the planarization layer 119.

The intermediate layer 220 may be arranged on the planarization layer 119. The intermediate layer 220 may include the first intermediate layer 220a arranged in the first region CA1, the second intermediate layer 220b arranged in the second region CA2, and the dummy intermediate layer 220d arranged on the top surface of the partition wall PW. The intermediate layer 220 may include a plurality of emitting units (e.g., a plurality of emitting layers or stacks), and the charge generation layer CGL arranged between the emitting units, as described above with reference to FIG. 3. In other words, each of the first organic light-emitting diode OLED1 and the second organic light-emitting diode OLED2 may be a tandem light-emitting device.

The intermediate layer 220 may be formed on the entire or substantially the entire surface of the display region DA through a thermal evaporation process. The intermediate layer 220 may be divided into the first intermediate layer 220a, the second intermediate layer 220b, and the dummy intermediate layer 220d, by the partition wall PW having the reverse tapered shape. A material for forming the intermediate layer 220 may have a low step coverage, and thus, may not be deposited on a side surface of the partition wall PW, or may be divided without being connected even when deposited on a portion of the side surface of the partition wall PW. The first intermediate layer 220a and the second intermediate layer 220b may be spaced apart from each other with the dummy intermediate layer 220d therebetween, thereby reducing or preventing a leakage current from flowing between the adjacent first organic light-emitting diode OLED1 and second organic light-emitting diode OLED2 through the intermediate layer 220. Therefore, the display panel 10 may display a high-quality image without a brightness unevenness or a color mixing.

The opposite electrode 230 may be arranged on the intermediate layer 220. The opposite electrode 230 may include the first conductive layer 231 and the second conductive layer 233. The first conductive layer 231 may include the first-first conductive layer 231a arranged in the first region CA1, the first-second conductive layer 231b arranged in the second region CA2, and the dummy conductive layer 231d arranged on the top surface of the partition wall PW.

The first conductive layer 231 may include silver (Ag) or a silver alloy, and may be formed on the entire or substantially the entire surface of the display region DA through a thermal evaporation process. The first conductive layer 231 may be divided into the first-first conductive layer 231a, the first-second conductive layer 231b, and the dummy conductive layer 231d, by the partition wall PW having the reverse tapered shape.

The second conductive layer 233 may include a transparent conductive oxide, and may be formed on the entire or substantially the entire surface of the display region DA through a sputtering process. The second conductive layer 233 has a relatively high step coverage, and thus, may extend to continuously cover the side surfaces and the top surface of the partition wall PW. In other words, the second conductive layer 233 may be commonly provided in the first organic light-emitting diode OLED1 and the second organic light-emitting diode OLED2.

An encapsulation layer 300 may be arranged on the second conductive layer 233. The encapsulation layer 300 may be arranged to cover the first organic light-emitting diode OLED1 and the second organic light-emitting diode OLED2. The encapsulation layer 300 may include at least one inorganic encapsulation layer and at least one organic encapsulation layer. In an embodiment, the encapsulation layer 300 may include a first inorganic encapsulation layer 310, an organic encapsulation layer 320 on the first inorganic encapsulation layer 310, and a second inorganic encapsulation layer 330 on the organic encapsulation layer 320. The first inorganic encapsulation layer 310 and the second inorganic encapsulation layer 330 may each include at least one inorganic material among aluminum oxide, titanium oxide, tantalum oxide, hafnium oxide, zinc oxide, silicon oxide, silicon nitride, and/or silicon oxynitride. The organic encapsulation layer 320 may include a polymer-based material. The polymer-based material may include an acryl-based resin, an epoxy-based resin, polyimide, and/or polyethylene. In an embodiment, the organic encapsulation layer 320 may include acrylate. The organic encapsulation layer 320 may be formed by curing a monomer or applying a polymer. The organic encapsulation layer 320 may have a transparency.

A color filter layer 400 may be arranged on the encapsulation layer 300. The color filter layer 400 may include a first color filter 410, a second color filter 420, and a third color filter, which transmit light of different colors from each other. The first color filter 410, the second color filter 420, and the third color filter may be arranged to correspond to the first to third pixels PX1, PX2, and PX3, respectively. For example, the first color filter 410 may be arranged to correspond to the first organic light-emitting diode OLED1, and the second color filter 420 may be arranged to correspond to the second organic light-emitting diode OLED2. For example, the first color filter 410 may be a green color filter that transmits green light among the light emitted from the intermediate layer 220. For example, the second color filter 420 may be a blue color filter that selectively transmits blue light among the light emitted from the intermediate layer 220. For example, the third color filter may be a red color filter that selectively transmits red light among the light emitted from the intermediate layer 220.

In an embodiment, the color filter layer 400 may further include a light-blocking layer that defines openings corresponding to organic light-emitting diodes. The light-blocking layer may be arranged between the first color filter 410, the second color filter 420, and the third color filter to reduce a color mixing of light passing through the color filter layer 400. In another embodiment, the color filter layer 400 may have a light-transmissive region corresponding to organic light-emitting diodes, and a light-blocking region outside the light-transmissive region. Only one color filter among the first color filter 410, the second color filter 420, and the third color filter may be arranged in the light-transmissive region, and at least two color filters among the first color filter 410, the second color filter 420, and the third color filter may overlap with each other in the light-blocking region.

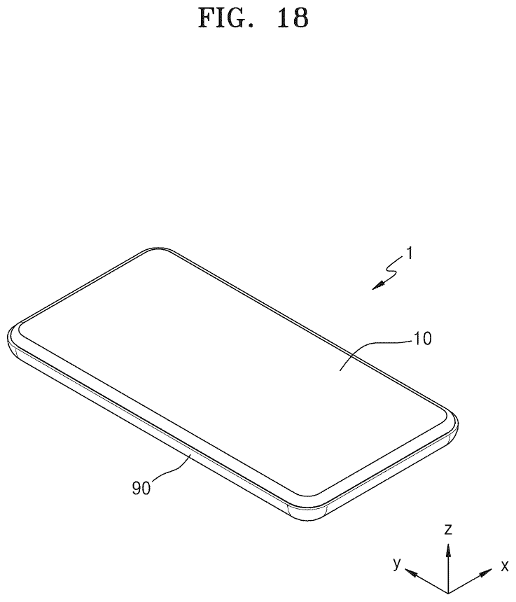

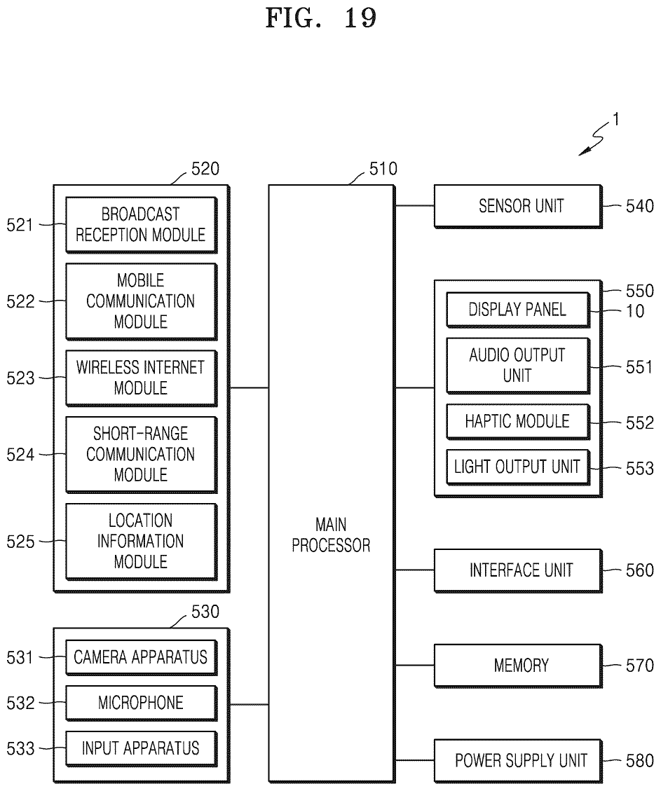

FIG. 18 is a perspective view schematically illustrating an electronic device according to an embodiment. FIG. 19 is a block diagram schematically illustrating an electronic device according to an embodiment.

Referring to FIGS. 18 and 19, an electronic device 1 including the display panel 10 according to an embodiment is an apparatus that displays a moving image or a still image, and may be used as display screens of various products such as televisions, laptops, monitors, billboards, or Internet of Things (IOTs) as well as portable electronic devices such as mobile phones, smartphones, tablet personal computers (tablet PCs), mobile communication terminals, electronic notebooks, e-books, portable multimedia players (PMPs), navigation devices, or ultra-mobile PCs (UMPCs). The electronic device 1 according to an embodiment may be used in wearable devices such as smart watches, watch phones, glasses-type displays, and head mounted displays (HMDs). The electronic device 1 according to an embodiment may be used as an instrument panel of vehicles, a center information display (CID) arranged on the center fascia or dashboard of vehicles, a room mirror display in place of side-view mirrors of vehicles, or a display arranged at the rear side of a front seat as an entertainment for a rear seat of vehicles.

FIG. 18 illustrates that the electronic device 1 according to an embodiment is used as a smartphone. The electronic device 1 may include the display panel 10 and a lower cover 90 arranged under the display panel 10. The electronic device 1 may include a cover window that covers a top surface of the display panel 10.

The lower cover 90 may form an exterior of the electronic device 1 and may have, in a front surface thereof, an opening exposing a portion of the display panel 10. The lower cover 90 has a shape in which a surface corresponding to the display panel 10 is open, and may be assembled with the display panel 10. The lower cover 90 may form an exterior of a lower surface of the electronic device 1, and a display circuit board, a component, a main circuit board, a battery, a driver, etc. may be arranged between the display panel 10 and the lower cover 90. The lower cover 90 may include plastic, metal, or both plastic and metal.

The electronic device 1 may include a main processor 510, a wireless communication unit 520, an input unit 530, a sensor unit 540, an output unit 550, an interface unit 560, a memory 570, and/or a power supply unit 580.

The main processor 510 may control all functions of the electronic device 1. For example, the main processor 510 may output digital video data to a data driver through the display circuit board such that the display panel 10 displays an image. The main processor 510 may receive sensing data from a touch sensor driving unit. The main processor 510 may determine whether there has been a user touch, based on the sensing data, and may execute an operation corresponding to the user's direct touch or proximity touch. The main processor 510 may be an application processor, a central processing unit, or a system chip, each including an integrated circuit.

A camera apparatus 531 processes an image frame, such as a still image or a moving image, obtained by an image sensor in camera mode, and outputs the processed image frame to the main processor 510. The camera apparatus 531 may include at least one of a camera sensor (e.g., CCD, CMOS, etc.), a photo sensor (e.g., an image sensor), and a laser sensor. The camera apparatus 531 may be connected to the image sensor and may process an image input to the image sensor.

The wireless communication unit 520 may include at least one of a broadcast reception module 521, a mobile communication module 522, a wireless Internet module 523, a short-range communication module 524, and a location information module 525.

The broadcast reception module 521 receives a broadcast signal and/or broadcast-related information from an external broadcast management server through a broadcast channel. The broadcast channel may include a satellite channel or a terrestrial channel.

The mobile communication module 522 may transceive a wireless signal to and from at least one of a base station, an external terminal, and a server over a mobile communication network built according to technology standards or communication methods (e.g., global system for mobile communication (GSM), code-division multiple access (CDMA), CDMA 2000, enhanced voice-data optimized or enhanced voice-data only (EV-DO), wideband CDMA (WCDMA), high speed downlink packet access (HSDPA), high speed uplink packet access (HSUPA), long-term evolution (LTE), LTE-advanced (LTE-A), etc.) for mobile communication. The wireless signal may include various types of data based on transmission and reception of voice call signals, video call signals, or text/multimedia messages.

The wireless Internet module 523 refers to a module for accessing wireless Internet. The wireless Internet module 523 may be configured to transceive a wireless signal in a communication network based on wireless Internet technologies. Wireless Internet technologies include, for example, wireless LAN (WLAN), wireless-fidelity (Wi-Fi), Wi-Fi Direct, Digital Living Network Alliance (DLNA), etc.

The short-range communication module 524 is for short-range communication, and may support short-range communication by using at least one of Bluetooth™, radio frequency identification (RFID), Infrared Data Association (IrDA), ultra wideband (UWB), ZigBee, near-field communication (NFC), Wi-Fi, Wi-Fi Direct, and wireless universal serial bus (wireless USB) technologies. The short-range communication module 524 may support, through wireless area networks, wireless communication between the electronic device 1 and a wireless communication system, between the electronic device 1 and another electronic apparatus, or between the electronic device 1 and a network where another electronic apparatus (e.g., external server) is located. The wireless area networks may be wireless personal area networks. The other electronic apparatus may be a wearable device that is capable of exchanging data with (e.g., interworking with) the electronic device 1.

The location information module 525 is a module for obtaining the location (e.g., current location) of the electronic device 1, and may include a global positioning system (GPS) module or a Wi-Fi module.

The input unit 530 may include an image input unit such as the camera apparatus 531 for inputting an image signal, an audio input unit such as a microphone 532 for inputting an audio signal, and an input apparatus 533 for receiving information from a user.

The camera apparatus 531 processes an image frame of a still image, a moving image, or the like, which is obtained by an image sensor, in a video call mode or a shooting mode. The processed image frame may be displayed on the display panel 10 or may be stored in the memory 570.

The microphone 532 processes an external audio signal into electrical voice data. The processed voice data may be utilized in various ways depending on a function (e.g., an application) being executed in the electronic device 1.

The main processor 510 may control the operation of the electronic device 1 to correspond to information input through the input apparatus 533. The input apparatus 533 may include a mechanical input means, such as a button, a dome switch, a jot wheel, a jog switch, etc., which is located on a rear surface or a side surface of the electronic device 1, or a touch input means. The touch input means may include a touch screen layer of the display panel 10.

The sensor unit 540 may include at least one sensor that senses at least one of information inside the electronic device 1, information about an environment surrounding the electronic device 1, and user information, and generates a corresponding sensing signal. Based on the sensing signal, the main processor 510 may control the driving or operation of the electronic device 1 or may perform data processing, a function, or an operation, which is each related to an application installed on the electronic device 1. The sensor unit 540 may include at least one of a proximity sensor, an illumination sensor, an acceleration sensor, a magnetic sensor, a gravity sensor (G-sensor), a gyroscope sensor, a motion sensor, an RGB sensor, an infrared (IR) sensor, a fingerprint scan sensor, an ultrasonic sensor, an optical sensor, a battery gauge, an environmental sensor (e.g., a barometer, a hygrometer, a thermometer, a radiation detection sensor, a heat detection sensor, a gas detection sensor, etc.), and a chemical sensor (e.g., an electronic nose, a healthcare sensor, a biometric sensor, etc.).

The output unit 550 is for generating output related to a visual, auditory, or tactile sense, or the like, and may include at least one of the display panel 10, an audio output unit 551, a haptic module 552, and a light output unit 553.

The display panel 10 may display (output) information processed by the electronic device 1. For example, the display panel 10 may display execution screen information of an application running on the electronic device 1, or user interface (UI) or graphic user interface (GUI) information according to the execution screen information. The display panel 10 may include a display layer that displays an image, and a touch screen layer that detects a user's touch input. Accordingly, the display panel 10 may function as the input apparatus 533 that provides an input interface between the electronic device 1 and the user, and at the same time, function as the output unit 550 that provides an output interface between the electronic device 1 and the user.

The audio output unit 551 may output audio data received from the wireless communication unit 520 or stored in the memory 570 in signal reception, call mode, or recording mode, voice recognition mode, broadcast reception mode, etc. The audio output unit 551 may also output an audio signal related to a function (e.g., call signal reception sound, message reception sound, etc.) performed in the electronic device 1. The audio output unit 551 may include a receiver or a speaker. At least one of the receiver and the speaker may be an audio generation apparatus that is attached to a lower portion of the display panel 10 and outputs audio by vibrating the display panel 10. The audio generation apparatus may be an piezoelectric element or a piezoelectric actuator, which each contracts and expands according to an electrical signal, or may be an exciter that generates magnetic force by using a voice coil to vibrate the display panel 10.

The haptic module 552 generates various tactile effects that may be felt by a user. The haptic module 552 may provide vibration to a user as a tactile effect. The haptic module 552 may not only transfer a tactile effect through direct contact, but may also be implemented such that a user may feel a tactile effect through a muscle sense such as a finger or an arm.

The light output unit 553 outputs a signal for notifying occurrence of an event by using light from a light source. Examples of the event that occurs in the electronic device 1 may include message reception, call signal reception, missed calls, alarms, schedule notification, email reception, and information reception through an application. The signal output by the light output unit 553 is generated by the electronic device 1 emitting monochromatic or multi-colored light from either a front surface or a rear surface thereof. The signal output may be terminated when the electronic device 1 detects a user's event acknowledgement.

The interface unit 560 serves as a conduit for various types of external devices connected to the electronic device 1. The interface unit 560 may include at least one of a wired/wireless headset port, an external charger port, a wired/wireless data part, a memory card port, a port for connecting an apparatus equipped with an identification module, an audio input/output (I/O) port, a video I/O port, and an earphone port. In response to an external device being connected to the interface unit 560, the electronic device 1 may perform appropriate control related to the connected external device.

The memory 570 stores data that supports various functions of the electronic device 1. The memory 570 may store a plurality of application programs running on the electronic device 1, data for the operation of the electronic device 1, and commands. At least some of the plurality of application programs may be downloaded from an external server through wireless communication. The memory 570 may store an application for the operation of the main processor 510, and may also temporarily store input/output data, for example, data such as a phonebook, a message, a still image, a moving image, etc. In addition, the memory 570 may store haptic data for various vibration patterns provided to the haptic module 552, and audio data relating to a variety of audio provided to the audio output unit 551. The memory 570 may include at least one type of storage medium among a flash memory type, a hard disk type, a solid state disk (SSD) type, a multimedia card micro type, a card type memory (e.g., SD or XD memory), random access memory (RAM), static RAM (SRAM), read-only memory (ROM), electrically erasable programmable ROM (EEPROM), programmable ROM (PROM), a magnetic memory, a magnetic disk, and an optical disk.

The power supply unit 580 receives external or internal power and supplies the power to each of components included in the electronic device 1, under control by the main processor 510. The power supply unit 580 may include a battery. In addition, the power supply unit 580 includes a connection port, and the connection port may be configured as an example of the interface unit 560 to which an external charger that supplies power for charging the battery is electrically connected. As another example, the power supply unit 580 may be configured to charge the battery wirelessly without using a connection port.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

According to an embodiment, a display panel capable of displaying a high-quality image and an electronic device including the display panel may be implemented. However, the present disclosure is not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
an insulating layer on a substrate;
a first pixel electrode on the insulating layer;
a partition wall on the insulating layer, and surrounding around the first pixel electrode in a plan view;
a first intermediate layer on the first pixel electrode; and
an opposite electrode on the first intermediate layer, and comprising:
a first conductive layer cut off by the partition wall; and
a second conductive layer on the first conductive layer, and extending to cover a side surface and a top surface of the partition wall.

2. The display panel of claim 1, further comprising:
a pixel-defining layer covering an edge of the first pixel electrode, and having a first pixel opening overlapping with the first pixel electrode;
wherein the partition wall is arranged on the pixel-defining layer, and
surrounding around the first pixel opening in a plan view, and
wherein the second conductive layer has a thickness of about 100 Å to about 900 Å on a surface parallel to the substrate.

3. The display panel of claim 1, wherein a cross-section of the partition wall has a reverse tapered shape.

4. The display panel of claim 3, wherein the side surface of the partition wall is inclined at an angle of about 130° to about 140° with respect to a top surface of the substrate.

5. The display panel of claim 3, wherein a distance from a bottom surface of the partition wall to the top surface of the partition wall is about 1.1 μm to about 3 μm.

6. The display panel of claim 2, wherein, in a plan view, a distance from a boundary of the first pixel opening to a boundary of the partition wall is about 4 μm to about 7.5 μm.

7. The display panel of claim 3, wherein, on the surface parallel to the substrate, the opposite electrode has a first thickness, and on the side surface of the partition wall, the opposite electrode has a second thickness that is about 20% to about 30% of the first thickness.

8. The display panel of claim 1, wherein the first intermediate layer comprises a plurality of emitting units.

9. The display panel of claim 1, further comprising:
a second pixel electrode and a third pixel electrode on the insulating layer, and spaced from the first pixel electrode; and
a second intermediate layer on the second pixel electrode and the third pixel electrode,
wherein the partition wall surrounds around the second pixel electrode and the third pixel electrode in a plan view.

10. The display panel of claim 9, further comprising:
a pixel-defining layer covering an edge of each of the first pixel electrode, the second pixel electrode and the third pixel electrode, and having a first pixel opening overlapping with the first pixel electrode, a second pixel opening overlapping with the second pixel electrode, and a third pixel opening overlapping with the third pixel electrode.

11. The display panel of claim 10, further comprising:
a spacer on the pixel-defining layer between the second pixel opening and the third pixel opening; and
an auxiliary partition wall on the spacer.

12. The display panel of claim 10, further comprising:
an auxiliary electrode on the insulating layer between the second pixel electrode and the third pixel electrode; and
an auxiliary partition wall on the auxiliary electrode,
wherein the pixel-defining layer has an auxiliary opening overlapping with the auxiliary electrode, and the second conductive layer is in direct contact with the auxiliary electrode.

13. A display panel comprising:
a first pixel electrode on a substrate;
a pixel-defining layer on the substrate, and having a first pixel opening overlapping with the first pixel electrode, and a groove surrounding around the first pixel electrode;
a first intermediate layer on the first pixel electrode; and
an opposite electrode on the first intermediate layer, and comprising:
a first conductive layer cut off by the groove; and
a second conductive layer on the first conductive layer, and extending to cover a side surface and a bottom surface of the groove.

14. The display panel of claim 13, wherein the side surface of the groove is inclined at an angle of about 40° to about 50° with respect to a top surface of the substrate.

15. The display panel of claim 13, wherein the first intermediate layer comprises a plurality of emitting units.

16. The display panel of claim 13, further comprising:
a second pixel electrode and a third pixel electrode on the substrate, and spaced from the first pixel electrode; and
a second intermediate layer on the second pixel electrode and the third pixel electrode,
wherein the pixel-defining layer has a second pixel opening overlapping with the second pixel electrode, and a third pixel opening overlapping with the third pixel electrode, and
wherein the groove completely surrounds around the second pixel opening and the third pixel opening in a plan view.

17. The display panel of claim 16, further comprising a spacer on the pixel-defining layer between the second pixel opening and the third pixel opening, the spacer having an auxiliary groove.

18. The display panel of claim 13,
wherein the groove extends along an inner surface of the first pixel opening, and the first intermediate layer is separated into a first portion disposed on the first pixel electrode and a second portion disposed on the pixel-defining layer by the groove.

19. The display panel of claim 18, further comprising a residual sacrificial layer between the pixel-defining layer and the edge of the first pixel electrode.

20. An electronic device comprising:
a display panel; and
a lower cover forming an exterior, and comprising a front surface having an opening exposing a portion of the display panel,
wherein the display panel comprises:
a pixel electrode on a substrate;
a pixel-defining layer covering an edge of the pixel electrode, and having a pixel opening overlapping with the pixel electrode;
an intermediate layer on the pixel electrode;
an opposite electrode on the intermediate layer; and
a separator surrounding around the pixel electrode in a plan view,
wherein the intermediate layer comprises a plurality of emitting units, and
wherein the opposite electrode comprises:
a first conductive layer cut off by the separator; and
a second conductive layer on the first conductive layer, and extending to cover the separator.
